(19) United States
(12) Patent Application Publication
(10) Pub. No.: US 2025/0270365 A1
(43) Pub. Date: Aug. 28, 2025

(54) ALKALI-SOLUBLE RESIN, ALKALI-SOLUBLE RESIN COMPOSITION AND METHOD FOR PRODUCING SAME

(71) Applicant: NIPPON SHOKUBAI CO., LTD., Osaka-shi, Osaka (JP)

(72) Inventors: Takuma TERADA, Suita-shi, Osaka (JP); Nobuaki OTSUKI, Suita-shi, Osaka (JP); Junya KIMURA, Suita-shi, Osaka (JP)

(21) Appl. No.: 18/850,429

(22) PCT Filed: Mar. 20, 2023
(86) PCT No.: PCT/JP2023/010890

§ 371 Date: Sep. 24, 2024

(30) Foreign Application Priority Data
Mar. 25, 2022 (JP) 2022-049766

(51) Int. Cl. C08G 59/17; C08F 8/14; C08F 8/44; C08F 290/06; C08G 59/22; C08G 59/24; C08G 59/62

(52) U.S. Cl. CPC C08G 59/1466; C08F 8/14; C08F 8/44; C08F 290/064; C08G 59/226; C08G 59/245; C08G 59/621

(57) ABSTRACT

The present invention aims to provide an alkali-soluble resin and an alkali-soluble resin composition capable of providing a cured product having excellent heat discoloration resistance and a high refractive index, and to provide a production method capable of efficiently producing these. The present invention relates to an alkali-soluble resin having a structure represented by the following formula (1), the alkali-soluble resin containing an ammonium salt compound in an amount of 0.06% by mass or less relative to 100% by mass of the alkali-soluble resin,
the formula (1) being as follows:

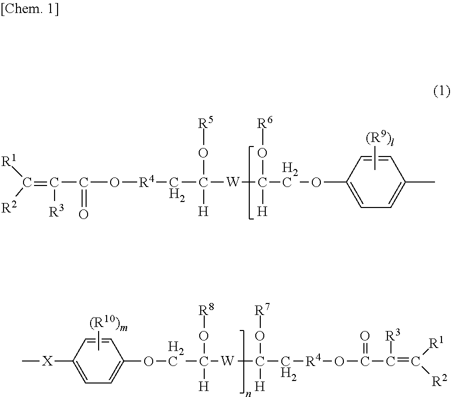

wherein R¹, R², and R³ are the same as or different from each other and each represent a hydrogen atom or a C1-C6 hydrocarbon group; R⁴ represents a direct bond or a divalent organic group; R⁵, R⁶, R⁷, and R⁸ are the same as or different from each other and each represent a hydrogen atom or Y, with at least one of R⁵ to R³ being Y, where Y is a group represented by the following formula (2); R⁹ and R¹⁰ are the same as or different from each other and each represent a substituent; W represents a divalent organic group; X represents a direct bond or a divalent organic group; l represents the number of R⁹ and is an integer of 0 to 4; m represents the number of R¹⁰ and is an integer of 0 to 4; when multiple R⁹s are present, they are the same as or different from each other, and when multiple R¹⁰s are present, they are the same as or different from each other; and n is an integer of 1 or more,
the formula (2) being as follows:

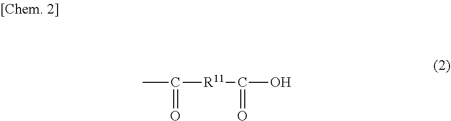

wherein R¹¹ represents a divalent organic group optionally containing a substituent.

### TECHNICAL FIELD

The present invention relates to an alkali-soluble resin and an alkali-soluble resin composition. Specifically, the present invention relates to an alkali-soluble resin and an alkali-soluble resin composition each capable of providing a cured product having excellent heat discoloration resistance and a high refractive index, and to a method for producing the same.

### BACKGROUND ART

Various studies have been made on photosensitive resin compositions containing alkali-soluble resins for their use in various applications for, for example, optical components and electrical or electronic devices such as color filters, inks, printing plates, printed wiring boards, semiconductor elements, photoresists, organic insulating films, and organic protective films used in liquid crystal display devices and solid-state imaging devices. Resins and resin compositions excellent in the properties required for these applications have been developed.

In recent years, optical components, electrical and electronic devices, and the like have become smaller, thinner, and more energy-efficient. As a result, higher quality performance has been demanded for various components and the like used therein. In response to such demands, studies have been conducted on alkali-soluble resins and photosensitive resin compositions that can be used as raw materials for various components and the like.

Up to now, photosensitive resin compositions containing alkali-soluble resins have been developed in response to various requirements.

For example, Patent Literature 1 describes a photosensitive resin composition for image formation containing an acid-modified vinyl ester which is synthesized from an epoxy compound, a phenol compound, an unsaturated monobasic acid, and a polybasic acid anhydride, wherein the epoxy compound at least partially contains a crystalline epoxy resin having a melting point of 90° C. or higher and the phenol compound at least partially contains a compound having a bisphenol S skeleton.

Also, for example, Patent Literature 2 discloses a photosensitive resin composition for image formation containing an epoxy acrylate and an acid-modified vinyl ester synthesized from a bifunctional epoxy compound, a bifunctional phenol compound, an unsaturated monobasic acid and/or an unsaturated monomer having a functional group capable of reacting with a phenolic hydroxy group, and a polybasic acid anhydride, wherein at least a part of the bifunctional epoxy compound or the bifunctional phenol compound has a biphenyl skeleton.

### CITATION LIST

### Patent Literature

Patent Literature 1: JP 2008-250306 A
Patent Literature 2: JP 2008-250307 A

### SUMMARY OF INVENTION

### Technical Problem

Although these alkali-soluble resins have excellent alkali developability, photocurability, and dimensional stability against temperature changes and can provide cured products that do not exhibit brittleness, the alkali-soluble resins are problematically prone to discoloration during heat curing. In addition, conventional alkali-soluble resins have low refractive indexes and are still insufficient for use in optical applications requiring high refractive indexes in which resins having a high refractive index of about 1.60 are needed.

The present invention has been made in consideration of the above-described current state and aims to provide an alkali-soluble resin and an alkali-soluble resin composition each capable of providing a cured product having excellent heat discoloration resistance and a high refractive index, and to provide a production method capable of efficiently producing these.

### Solution to Problem

The present inventors have conducted various studies on alkali-soluble resins and have found that an alkali-soluble resin which has a specific structure and in which the amount of an ammonium salt compound is within a specific range can provide a cured product having excellent heat discoloration resistance and a high refractive index. Thereby, the present invention has been completed.

Specifically, the present invention relates to an alkali-soluble resin having a structure represented by the following formula (1), the alkali-soluble resin containing an ammonium salt compound in an amount of 0.06% by mass or less relative to 100% by mass of the alkali-soluble resin, the formula (1) being as follows:

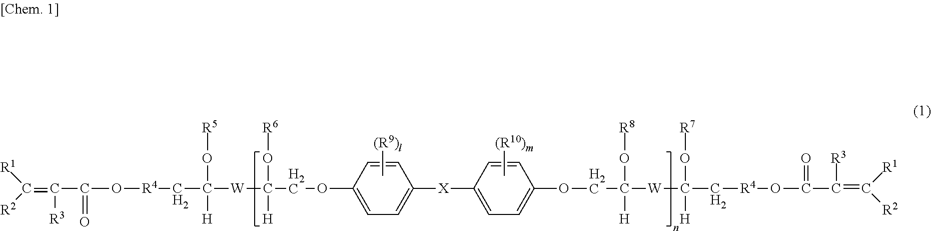

wherein R¹, R², and R³ are the same as or different from each other and each represent a hydrogen atom or a C1-C6 hydrocarbon group; R⁴ represents a direct bond or a divalent organic group; R⁵, R, R⁷, and R⁸ are the same as or different from each other and each represent a hydrogen atom or Y, with at least one of R⁵ to R³ being Y, where Y is a group represented by the following formula (2); R⁹ and R¹⁰ are the same as or different from each other and each represent a substituent; W represents a divalent organic group; X represents a direct bond or a divalent organic group; 1 represents the number of R⁹ and is an integer of 0 to 4; m represents the number of R¹⁰ and is an integer of 0 to 4; when multiple R⁹s are present, they are the same as or different from each other, and when multiple R¹⁰s are present, they are the same as or different from each other; and n is an integer of 1 or more, the formula (2) being as follows:

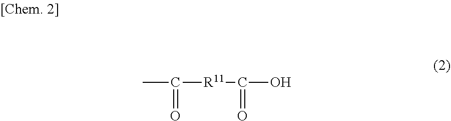

wherein R¹¹ represents a divalent organic group optionally containing a substituent.

The present invention also relates to an alkali-soluble resin composition containing: the alkali-soluble resin; and an acid group-containing epoxy (meth)acrylate.

The present invention also relates to a method for producing an alkali-soluble resin, the method including: a step (a-1) of reacting a bisphenol compound with a bifunctional epoxy compound having a Gardner color scale based on JIS K 0071-2 of less than 12 and a melting point of 90° C. or higher; a step (a-2) of reacting a reaction product obtained in the step (a-1) with an unsaturated monobasic acid; and a step (a-3) of reacting a reaction product obtained in the step (a-2) with a polybasic acid anhydride, wherein the alkali-soluble resin obtained by the production method contains an ammonium salt compound in an amount of 0.06% by mass or less relative to 100% by mass of the alkali-soluble resin.

The present invention also relates to a method for producing an alkali-soluble resin composition, the method including: a step (b-1) of reacting a bisphenol compound with a bifunctional epoxy compound having a Gardner color scale based on JIS K 0071-2 of less than 12 and a melting point of 90° C. or higher; a step (b-2) of adding an epoxy resin to a reaction product obtained in the step (b-1); a step (b-3) of reacting a mixture obtained in the step (b-2) with an unsaturated monobasic acid; and a step (b-4) of reacting a reaction mixture obtained in the step (b-3) with a polybasic acid anhydride, wherein the alkali-soluble resin composition obtained by the production method contains an ammonium salt compound in an amount of 0.06% by mass or less relative to 100% by mass of the alkali-soluble resin.

Preferably, the epoxy resin is an aromatic epoxy resin.

Preferably, the aromatic epoxy resin is a bisphenol A epoxy resin.

### Advantageous Effects of Invention

The alkali-soluble resin and alkali-soluble resin composition of the present invention are capable of providing cured products having excellent heat discoloration resistance and high refractive indexes. The alkali-soluble resin and alkali-soluble resin composition of the present invention can be widely used in various applications for optical components, electrical and electronic components, display devices, and the like.

### DESCRIPTION OF EMBODIMENTS

The present invention is described in detail below.

Any combination of two or more of the following preferred embodiments of the present invention is also a preferred embodiment of the present invention.

Herein, “(meth) acrylate” refers to “acrylate and/or methacrylate” and “(meth)acrylic acid” refers to “acrylic acid and/or methacrylic acid”.

### 1. Alkali-Soluble Resin

An alkali-soluble resin of the present invention is an alkali-soluble resin having a structure represented by the following formula (1), the alkali-soluble resin containing an ammonium salt compound in an amount of 0.06% by mass or less relative to 100% by mass of the alkali-soluble resin. The formula (1) is as follows:

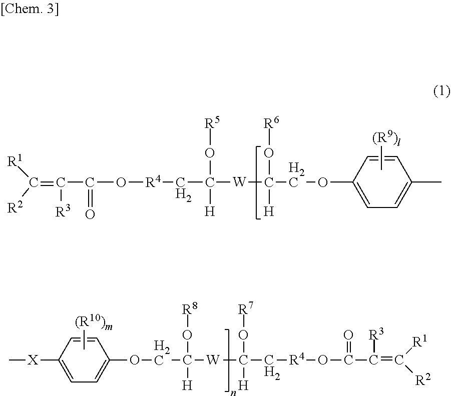

wherein R¹, R², and R³ are the same as or different from each other and each represent a hydrogen atom or a C1-C6 hydrocarbon group; R⁴ represents a direct bond or a divalent organic group; R⁵, R, R⁷, and R⁸ are the same as or different from each other and each represent a hydrogen atom or Y, with at least one of R⁵ to R³ being Y, where Y is a group represented by the following formula (2); R⁹ and R¹⁰ are the same as or different from each other and each represent a substituent; W represents a divalent organic group; X represents a direct bond or a divalent organic group; 1 represents the number of R⁹ and is an integer of 0 to 4; m represents the number of R¹⁰ and is an integer of 0 to 4; when multiple R⁹s are present, they are the same as or different from each other, and when multiple R¹⁰s are present, they are the same as or different from each other; and n is an integer of 1 or more. The formula (2) is as follows:

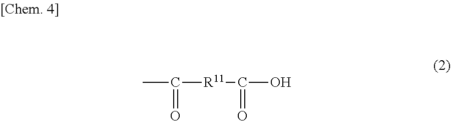

wherein R¹ represents a divalent organic group optionally containing a substituent.

The alkali-soluble resin of the present invention can provide a cured product having excellent heat discoloration resistance. This is presumably because the amount of the ammonium salt compound in the resin is not greater than a predetermined range of amount, so that the amount of nitrogen, which can cause discoloration during heat curing, is low, whereby discoloration during heat curing can be prevented or reduced. In addition, the alkali-soluble resin of the present invention has a high refractive index. This is believed to be because the alkali-soluble resin has a rigid skeleton in the main chain, such as a biphenyl skeleton or a skeleton in which aromatic rings are linked via a divalent organic group, and thus can form a dense cured film by the n-n stacking effect.

The alkali-soluble resin of the present invention has a structure represented by the formula (1).

In the formula (1), R¹, R², and R³ are the same as or different from each other and each represent a hydrogen atom or a C1-C6 hydrocarbon group.

An example of the C1-C6 hydrocarbon group is a C1-C6 chain or cyclic hydrocarbon group. It is preferably a C1-C6 chain hydrocarbon group, more preferably a C1-C6 alkyl group.

Of these, to achieve good reactivity of the unsaturated double bond, preferably, R¹, R², and R³ are the same as or different from each other and are each a hydrogen atom or a methyl group, and more preferably, R¹ and R² are hydrogen atoms and R³ is a hydrogen atom or a methyl group.

In the formula (1), R⁴ represents a direct bond or a divalent organic group.

Examples of the divalent organic group for R⁴ include —O—, —CO—, —NH—, —S—, —SO—, —SO₂—, a divalent hydrocarbon group optionally containing a substituent, and a combination thereof. Of these, to achieve better heat discoloration resistance, the divalent organic group is preferably —O—, —CO—, a divalent hydrocarbon group optionally containing a substituent, or a combination thereof, more preferably a group consisting of a combination of the divalent hydrocarbon group, —O—, and —CO—.

The divalent hydrocarbon group may be a saturated hydrocarbon group or an unsaturated hydrocarbon group. It is preferably a saturated hydrocarbon group to achieve better heat discoloration resistance.

The divalent hydrocarbon group may be either a chain (linear or branched) group or a cyclic group, preferably a chain group to achieve excellent dimensional stability.

Examples of the divalent hydrocarbon group include a divalent aliphatic hydrocarbon group, an alicyclic hydrocarbon group, and an aromatic hydrocarbon group.

Examples of the divalent aliphatic hydrocarbon group include alkylene groups such as a methylene group, an ethylene group, a propylene group, an isopropylene group, a butylene group, an isobutylene group, a t-butylene group, a pentylene group, a neopentylene group, a hexamethylene group, a heptylene group, an octylene group, a 2-ethylhexylene group, a nonylene group, a decylene group, an undecylene group, and a dodecylene group; and alkenylene groups such as a vinylene group, a propenylene group, an isopropenylene group, a butenylene group, a butadienylene group, a pentenylene group, a hexenylene group, and a heptenylene group.

Examples of the divalent alicyclic hydrocarbon group include cycloalkylene groups such as a cyclopropylene group, a cyclobutylene group, a cyclopentylene group, a cyclohexylene group, a norbornylene group, and an adamantylene group; and cycloalkylidene groups such as a cyclopentylidene group and a cyclohexylidene group.

Examples of the divalent aromatic hydrocarbon group include arylene groups such as a phenylene group, a tolylene group, and a naphthylene group; a cinnamylidene group; and a biphenylene group.

Preferred of these divalent hydrocarbon groups are a divalent aliphatic hydrocarbon group and a divalent alicyclic hydrocarbon group, with a divalent aliphatic hydrocarbon group being more preferred and an alkylene group being still more preferred.

To achieve excellent dimensional stability, the divalent hydrocarbon group preferably has 1 to 7 carbon atoms, more preferably 1 to 5 carbon atoms, still more preferably 1 to 3 carbon atoms.

Examples of the substituent optionally contained in the divalent hydrocarbon group include a carboxy group, a hydroxy group, an alkoxy group, a halogen atom, and a C1-C7 hydrocarbon group.

Preferred specific examples of the divalent organic group for R⁴ include —R^{a}—COO—, —R^{a}—OCO—R^{a}—COO—, and —R^{a}—COO—R^{a}—COO—, where R^{a}s are the same as or different from each other and each represent a divalent organic group optionally containing a substituent. More preferred is —R^{a}—COO—, where R^{a} represents a divalent hydrocarbon group.

Most preferably, R⁴ is a direct bond.

In the formula (1), R⁵, R⁶, R⁷, and R⁸ are the same as or different from each other and each represent a hydrogen atom or Y, with at least one of R⁵, R⁶, R⁷, and R⁸ being Y. The symbol Y is a group represented by the formula (2).

In the formula (2), R¹¹ is a divalent organic group optionally containing a substituent. Examples of the divalent organic group for R¹¹ include the same groups as the divalent organic groups described above. Of these, the divalent organic group is preferably a divalent hydrocarbon group, more preferably a divalent aliphatic hydrocarbon group, an alicyclic hydrocarbon group, or an aromatic hydrocarbon group, still more preferably a divalent aliphatic hydrocarbon group or an alicyclic hydrocarbon group.

The number of carbon atoms of the divalent organic group for R¹¹ is preferably 1 to 20, more preferably 1 to 10, still more preferably 1 to 8, further preferably 2 to 6, particularly preferably 2 or 6, most preferably 6.

Examples of the substituent optionally contained in the divalent organic group for R¹¹ include a carboxy group and a C1-C20 hydrocarbon group. To improve the alkali solubility, preferred of these is a carboxy group.

In the formula (1), W represents a divalent organic group.

Examples of the divalent organic group for W include the divalent organic groups described above, with —O—, a divalent hydrocarbon group optionally containing a substituent, or a combination thereof being more preferred, of these.

Examples of the divalent hydrocarbon group include the divalent hydrocarbon groups described above, with a divalent aromatic hydrocarbon group being preferred and a biphenylene group being more preferred, of these.

Examples of the substituent optionally contained in the divalent hydrocarbon group include a C1-C10 hydrocarbon group, a halogen atom, and a cyano group.

A preferred specific example of the divalent organic group for W is a group represented by the following formula (3):

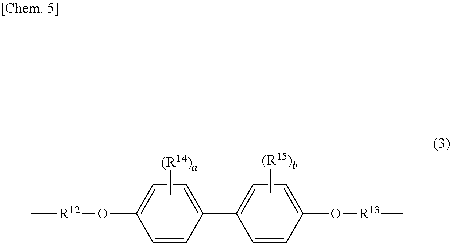

wherein R¹² and R¹³ are the same as or different from each other and each represent a divalent hydrocarbon group; R¹⁴ and R¹⁵ are the same as or different from each other and each represent a substituent; a represents the number of R¹⁴ and is an integer of 0 to 4; and b represents the number of R¹⁵ and is an integer of 0 to 4.

Preferred examples of the divalent hydrocarbon group(s) for R¹² and R¹³ include the divalent hydrocarbon groups described above. Preferred of these is a divalent aliphatic hydrocarbon group, with a C1-C3 saturated divalent aliphatic hydrocarbon group being more preferred and a methylene group being still more preferred.

Non-limiting examples of the substituent(s) for R¹⁴ and R¹⁵ include any monovalent substituents. In particular, a hydrocarbon group is preferred, a C1-C10 hydrocarbon group is more preferred, a C1-C5 aliphatic hydrocarbon group is still more preferred, a C1-C5 saturated aliphatic hydrocarbon group is further preferred, and a methyl group is most preferred.

The symbol a is an integer of 0 to 4, preferably 0 to 2, more preferably 2.

The symbol b is an integer of 0 to 4, preferably 0 to 2, more preferably 2.

In the formula (1), X represents a direct bond or a divalent organic group.

Examples of the divalent organic group for X include the divalent organic groups described above. Of these, —SO₂—, a divalent hydrocarbon group optionally containing a substituent, or a combination thereof is preferred, —SO₂— or a C1-C20 divalent hydrocarbon group optionally containing a substituent is more preferred, a C1-C10 divalent aliphatic hydrocarbon group or —SO₂— is still more preferred, a C1-C5 divalent saturated aliphatic hydrocarbon group or —SO₂— is further preferred, and —SO₂— is most preferred. The presence of a S atom can make the refractive index higher.

Examples of the substituent include the substituents described above. Preferred of these are halogen atoms such as a fluorine atom, a chlorine atom, and an iodine atom.

When the divalent hydrocarbon group has a ring structure, the substituent is preferably a halogen atom, an alkyl group, or the like.

Of these, X is preferably a direct bond, an alkylene group, or —SO₂—, more preferably a direct bond, a C1-C10 alkylene group, or —SO₂—, still more preferably a direct bond or —SO₂—.

When n is 2 or more, the multiple Xs are the same as or different from each other.

In the formula (1), R⁹ and R¹⁰ are the same as or different from each other and each represent a substituent.

Examples of the substituent for R⁹ or R¹⁰ include any monovalent substituents, such as a carboxy group, a hydroxy group, an amino group, a C1-C20 hydrocarbon group, a halogen atom, or a group including a combination thereof.

Any substituent among these substituents allows the alkali-soluble resin to form a dense cured product due to the stacking interaction of the aromatic rings, providing a cured product with a high refractive index.

The symbol l represents the number of substituents R⁹ and is an integer of 0 to 4, preferably 0 to 2, more preferably 0 or 2, still more preferably 0.

The symbol m represents the number of substituents R¹⁰ and is an integer of 0 to 4, preferably 0 to 2, more preferably 0 or 2, still more preferably 0.

When multiple R⁹ are present, they are the same as or different from each other, and when multiple R¹⁰ are present, they are the same as or different from each other.

The symbol n is an integer of 1 or more.

The alkali-soluble resin contains an ammonium salt compound in an amount of 0.06% by mass or less relative to 100% by mass of the alkali-soluble resin. When the amount of the ammonium salt compound in the alkali-soluble resin is 0.06% by mass or less, a cured product having excellent heat discoloration resistance can be obtained. Conventionally, an ammonium salt compound such as benzyltriethylammonium chloride has been used as a catalyst to synthesize the alkali-soluble resin described above. The present invention is based on findings that such an ammonium salt compound causes deterioration of the heat discoloration resistance of the alkali-soluble resin and that the heat discoloration resistance of the alkali-soluble resin is significantly improved by reducing the amount of the ammonium salt compound in the alkali-soluble resin to a predetermined amount or less.

The amount of the ammonium salt compound is more preferably 0.03% by mass or less, still more preferably 0.01% by mass or less, most preferably 0% by mass, relative to 100% by mass of the alkali-soluble resin, to achieve better heat discoloration resistance.

Examples of the ammonium salt compound include quaternary ammonium salts such as benzyltriethylammonium chloride, benzyltrimethylammonium chloride, tetra-n-butylammonium chloride, tetraethylammonium chloride, tetramethylammonium chloride, and bromides of these.

The amount of the ammonium salt compound can be determined by quantitative determination of ammonium ions by ion chromatography and/or mass spectrometry. Alternatively, it can also be calculated by dividing the mass of the ammonium salt compound used by the sum of the masses of the monomer components constituting the alkali-soluble resin having a structure represented by the formula (1).

The alkali-soluble resin preferably has an acid value of 30 to 150 mgKOH/g, more preferably 40 to 135 mgKOH/g, further preferably 50 to 120 mgKOH/g, most preferably 70 to 100 mgKOH/g.

The acid value is a value obtained by measurement using a neutralization titration method with a potassium hydroxide (KOH) solution, and is an acid value per gram of resin solids.

The alkali-soluble resin preferably has a weight average molecular weight of 400 to 30000. The weight average molecular weight of the alkali-soluble resin is more preferably 1000 to 10000, still more preferably 2000 to 5000, further preferably 2500 to 3500, to increase the developing rate.

The weight average molecular weight is a value obtained by measurement using gel permeation chromatography (GPC). Specifically, it can be measured by a GPC method with polystyrene as a standard substance, tetrahydrofuran as an eluent, HLC-8220GPC (Tosoh Corporation), and a TSKgel Super HZM-M column (Tosoh Corporation).

The alkali-soluble resin preferably has a double bond equivalent of 500 to 2000 g/eq. To improve the curability, the double bond equivalent is more preferably 530 to 1500 g/eq, still more preferably 550 to 1100 g/eq, further preferably 570 to 900 g/eq.

The double bond herein refers to a radically polymerizable double bond. In other words, the double bond refers to double bonds typified by a (meth)acryloyl group. For example, a double bond such as that generated by adding tetrahydrophthalic anhydride to a OH group has no reactivity and thus shall not be included in the calculation of the double bond equivalent.

The double bond equivalent refers to the mass of the solids in the polymer solution per mole of double bonds in the resin. The mass of the solids in the polymer solution is the mass of the monomer components constituting the resin. The double bond equivalent can be determined by dividing the mass (g) of the resin solids in the polymer solution by the amount of double bonds (mol) in the resin. The double bond equivalent can also be determined by various analyses such as titration, elemental analysis, NMR, and IR, as well as differential scanning calorimetry. For example, it may be calculated by measuring the number of ethylenic double bonds contained in 1 g of the resin in accordance with the test method for iodine value described in JIS K 0070:1992.

### 2. Method for Producing Alkali-Soluble Resin

The alkali-soluble resin may be produced by any method that can produce an alkali-soluble resin having the above-described structure. The method may be appropriately selected from known polymerization methods. In particular, to efficiently produce the alkali-soluble resin, the method for producing an alkali-soluble resin preferably includes a step (a-1) of reacting a bisphenol compound with a bifunctional epoxy compound having a Gardner color scale based on JIS K 0071-2 of less than 12 and a melting point of 90° C. or higher; a step (a-2) of reacting a reaction product obtained in the step (a-1) with an unsaturated monobasic acid; and a step (a-3) of reacting a reaction product obtained in the step (a-2) with a polybasic acid anhydride. These steps are described below.

Step (a-1)

In the production method, first, a bifunctional epoxy compound having a Gardner color scale based on JIS K 0071-2 of less than 12 and a melting point of 90° C. or higher is reacted with a bisphenol compound.

In the reaction in the step (a-1), the epoxy groups of the bifunctional epoxy compound react with the phenolic hydroxy groups of the bisphenol compound to produce a compound in which the bifunctional epoxy compound and the bisphenol compound are linked together.

The bifunctional epoxy compound used in this reaction step preferably has a Gardner color scale based on JIS K 0071-2 of less than 12 and a melting point of 90° C. or higher. When the bifunctional epoxy compound has a Gardner color scale of less than 12, the resulting alkali-soluble resin can provide a cured product having excellent heat discoloration resistance, flexibility, and refractive index. This is believed to be because the use of a raw material having a specified Gardner color scale can reduce the oxidative degradation of the product caused by oxygen.

The Gardner color scale of the bifunctional epoxy compound is more preferably less than 11, still more preferably less than 10, most preferably less than 8, to provide an alkali-soluble resin having further improved heat discoloration resistance.

The melting point of the bifunctional epoxy compound is more preferably 95° C. or higher, still more preferably 100° C. or higher, to achieve excellent heat resistance.

The bifunctional epoxy compound preferably has an epoxy equivalent of 150 to 300 g/eq, more preferably 160 to 250 g/eq, still more preferably 170 to 200 g/eq.

The epoxy equivalent can be determined by a method in accordance with JIS K 7236:2001, specifically, by the method described in the EXAMPLES below.

The bifunctional epoxy compound may be any compound satisfying the above-described Gardner color scale and melting point and having two epoxy groups. A preferred example thereof is a compound represented by the following formula (4):

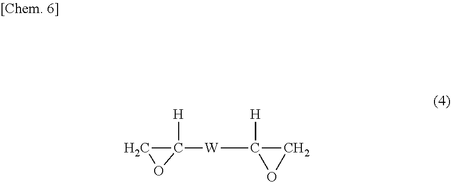

wherein W represents a divalent organic group.

In the formula (4), W is preferably the same divalent organic group as W in the formula (1).

The compound represented by the formula (4) may have a molecular weight distribution. The compound represented by the formula (4) preferably has a weight average molecular weight of 80 to 5000, more preferably 100 to 1000, still more preferably 150 to 500.

The weight-average molecular weight is a value obtained by measurement using gel permeation chromatography (GPC).

The compound represented by the formula (4) can be synthesized by a known method, such as the method described in JP 2016-108562 A. Typically, it is synthesized by adding epichlorohydrin to a biphenol compound.

The bifunctional epoxy compound may also be a commercial product, and examples thereof include YL6121H and YX4000 (Mitsubishi Chemical Corporation) and YDC-1312 and YSLV-120TE (Nippon Steel Chemical & Material Co., Ltd.).

These bifunctional epoxy compounds may be used alone or in combination of two or more.

The bisphenol compound may be any compound having two phenolic hydroxy groups. A preferred example thereof is a compound represented by the following formula (5):

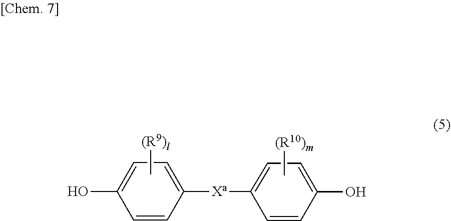

wherein X represents a direct bond or a divalent organic group; R⁹ and R¹⁰ are the same as or different from each other and each represent a substituent; 1 represents the number of R⁹ and is an integer of 0 to 4; m represents the number of R¹⁰ and is an integer of 0 to 4; when multiple R⁹s are present, they are the same as or different from each other; and when multiple R¹⁰ s are present, they are the same as or different from each other.

X, R⁹, and R¹⁰ in the formula (5) are preferably the same as X, R⁹, and R¹⁰ in the formula (1), respectively. Moreover, 1 and m in the formula (5) are preferably the same as 1 and m in the formula (1), respectively.

Specific examples of the bisphenol compound include bisphenol A, bisphenol AP, bisphenol AF, bisphenol B, bisphenol BP, bisphenol C, bisphenol E, bisphenol F, bisphenol G, bisphenol M, bisphenol S, bisphenol TMC, bisphenol P, bisphenol PH, and bisphenol Z.

Preferred of these are bisphenol A, bisphenol F, and bisphenol S, with bisphenol S being more preferred because they are relatively easily available.

These bisphenol compounds may be used alone or in combination of two or more.

The reaction of the bifunctional epoxy compound with the bisphenol compound can be performed by mixing these components in a solvent.

As for the mixing ratio of the bisphenol compound to the bifunctional epoxy compound, the amount of the bisphenol compound is preferably 10 to 60 parts by mass, more preferably 15 to 55 parts by mass, still more preferably 20 to 50 parts by mass, most preferably 30 to 40 parts by mass, relative to 100 parts by mass of the bifunctional epoxy compound.

Examples of the solvent include ethers such as tetrahydrofuran, dioxane, ethylene glycol dimethyl ether, and diethylene glycol dimethyl ether; ketones such as acetone and methyl ethyl ketone; esters such as ethyl acetate, butyl acetate, cellosolve acetate, carbitol acetate, (di)propylene glycol monomethyl ether acetate, and 3-methoxybutyl acetate; aromatic hydrocarbons such as toluene, xylene, and ethylbenzene; chloroform; dimethyl sulfoxide; and dimethyl carbonate. Preferred of these are esters, with carbitol acetate and (di)propylene glycol monomethyl ether acetate being more preferred. These solvents may be used alone or in combination of two or more.

In the reaction described above, a reaction catalyst is preferably used. The reaction catalyst used is preferably a compound other than the above-described ammonium salt compounds. Examples thereof include tertiary amines such as trimethylamine, triethylamine, tributylamine, tripropylamine, and trihexylamine; tertiary phosphines such as triphenylphosphine; quaternary phosphonium salts such as benzyltriphenylphosphonium bromide; and chelate compounds. Preferred of these reaction catalysts are tertiary phosphines such as triphenylphosphine because of their excellent activity. Furthermore, the use of a tertiary phosphine can provide a cured product having improved voltage holding properties.

These reaction catalysts may be used alone or in combination of two or more.

Metal compounds, which have electrical conductivity, may deteriorate the electrical properties of the composition. Thus, use of a catalyst containing a metal atom is unpreferred.

The amount of the reaction catalyst is preferably, but not limited to, 0.05 to 5 parts by mass, more preferably 0.07 to 1 part by mass, still more preferably 0.08 to 0.8 parts by mass, most preferably 0.1 to 0.6 parts by mass, relative to 100 parts by mass of the bifunctional epoxy compound.

The reaction temperature of the reaction described above is preferably, but not limited to, 80° C. to 150° C., more preferably 85° C. to 145° C., still more preferably 90° C. to 140° C.

The reaction time is preferably, but not limited to, 2 to 10 hours, more preferably 3 to 9 hours, still more preferably 4 to 8 hours.

The reaction may be performed in an air atmosphere or in an inert gas atmosphere such as nitrogen or argon. In particular, an inert gas atmosphere is preferred to prevent or reduce deactivation of the catalyst.

Step (a-2)

The step (a-2) includes reacting the reaction product obtained in the step (a-1) with an unsaturated monobasic acid. Through this reaction, the unsaturated monobasic acid reacts with the epoxy groups of the bifunctional epoxy compound, and a radically polymerizable unsaturated bond is introduced to an end of the reaction product.

An example of the unsaturated monobasic acid is a monobasic acid having one carboxy group and one or more radically polymerizable unsaturated bonds. Specific examples include acrylic acid, methacrylic acid, crotonic acid, cinnamic acid, β-acryloxypropionic acid, a reaction product of a hydroxyalkyl (meth)acrylate having one hydroxy group and one (meth)acryloyl group with a dibasic acid anhydride, a reaction product of a polyfunctional (meth)acrylate having one hydroxy group and two or more (meth)acryloyl groups with a dibasic acid anhydride, and caprolactone-modified products of these monobasic acids.

To achieve good reactivity of the unsaturated double bond, preferred of these unsaturated monobasic acids is a compound having a (meth)acryloyl group, such as acrylic acid or methacrylic acid, with acrylic acid or methacrylic acid being more preferred and methacrylic acid being most preferred.

These unsaturated monobasic acids may be used alone or in combination of two or more.

The unsaturated monobasic acid to be reacted is preferably added in an amount such that the acid groups in the unsaturated monobasic acid is 0.6 to 1.4 mol per mole of the epoxy groups in the reaction product obtained in the step (a-1). The amount is more preferably 0.7 to 1.3 mol, still more preferably 0.8 to 1.2 mol, further preferably 1.0 to 1.1 mol. If the epoxy groups remain in the resin, the storage stability may deteriorate.

The unsaturated monobasic acid may be added all at once, or may be added in portions or sequentially. To prevent or reduce side reactions, it is preferably added in portions or sequentially.

In the reaction in the step (a-2), an addition catalyst is preferably used.

The addition catalyst may be the same as the reaction catalyst used in the step (a-1). Examples thereof include tertiary amines such as trimethylamine, triethylamine, tributylamine, tripropylamine, and trihexylamine; tertiary phosphines such as triphenylphosphine; quaternary phosphonium salts such as benzyltriphenylphosphonium bromide; and chelate compounds. These may be used alone or in combination of two or more.

Preferred of these addition catalysts are tertiary phosphines such as triphenylphosphine.

Metal compounds, which have electrical conductivity, may deteriorate the electrical properties of the composition. Thus, use of a catalyst containing a metal atom is unpreferred.

The amount of the addition catalyst is preferably, but not limited to, 0.05 to 5 parts by mass, more preferably 0.1 to 4 parts by mass, still more preferably 0.2 to 3 parts by mass, most preferably 0.5 to 2.5 parts by mass, relative to 100 parts by mass of the bifunctional epoxy compound. When a reaction catalyst is used in the step (a-1), the amount of the catalyst herein refers to the sum of the amount of the addition catalyst and the amount of the reaction catalyst.

When the same catalyst is used as both the reaction catalyst and the addition catalyst in the reactions in the step (a-1) and the step (a-2), a total amount of the catalyst to be used in the production process may be added all at once in the step (a-1), and is preferably added in portions in the step (a-1) and the step (a-2). By adding the catalyst in portions, a decrease in catalytic activity can be prevented or reduced. In particular, when the catalyst is a tertiary phosphine, it is oxidized in the presence of oxygen and loses the catalytic activity. To compensate for such deactivation, the catalyst is preferably added in portions. If a large amount of phosphine is used in the early stage in anticipation of deactivation of the catalyst, a resin with increased discoloration may be obtained because the oxidized phosphine is yellowish.

When the catalyst is added in portions in the step (a-1) and the step (a-2), the ratio of the amounts of catalyst added in the steps represented by “the amount of catalyst added in the step (a-1)/the amount of catalyst added in the step (a-2)” is preferably 5/95 to 95/5, more preferably 10/90 to 90/10, still more preferably 15/85 to 85/15, further preferably 20/80 to 80/20.

In each of the steps (a-1) and (a-2), the catalyst may be added all at once, may be added in portions, or may be added sequentially in small portions. To prevent or reduce the decrease in catalytic activity, the catalyst is preferably added in portions or added sequentially in small portions.

In the reaction in the step (a-2), a polymerization inhibitor may be used. The use of a polymerization inhibitor can prevent or reduce gelation.

The polymerization inhibitor may be any known inhibitor. Examples include benzoquinone, hydroquinones (e.g., hydroquinone, methylhydroquinone, hydroquinone monomethyl ether, p-tert-butylhydroquinone, p-benzoquinone), phenols (e.g., 2,6-di-t-butyl-4-methylphenol, 6-t-butyl-2,4-dimethylphenol, 2,2′-methylenebis(4-methyl-6-t-butylphenol)), catechols (e.g., p-tert-butylcatechol), amines (e.g., N,N-diethylhydroxylamine), 1,1-diphenyl-2-picrylhydrazyl, tri-p-nitrophenylmethyl, phenothiazine, piperidine 1-oxyls (e.g., 2,2,6,6-tetramethylpiperidine 1-oxyl), and oxygen. Of these, hydroquinones are preferred to further improve the heat discoloration resistance of the alkali-soluble resin, and hydroquinone is preferred to improve the flexibility of a cured product of the alkali-soluble resin.

These polymerization inhibitors may be used alone or in combination of two or more.

As for the reaction conditions of the step (a-2), the reaction temperature is preferably, but not limited to, 80° C. to 140° C., more preferably 85° C. to 135° C., still more preferably 90° C. to 130° C. The reaction time is preferably, but not limited to, 5 to 30 hours, more preferably 6 to 25 hours, still more preferably 7 to 20 hours.

Step (a-3)

The step (a-3) includes reacting the reaction product obtained in the step (a-2) with a polybasic acid anhydride. In the reaction in the step (a-3), a polybasic acid anhydride is added to the hydroxy groups of the reaction product obtained in the step (a-2), and an acid group such as a carboxy group is introduced into the reaction product.

Examples of the polybasic acid anhydride include dibasic acid anhydrides such as phthalic anhydride, succinic anhydride, octenylsuccinic anhydride, pentadodecenylsuccinic anhydride, maleic anhydride, tetrahydrophthalic anhydride, hexahydrophthalic anhydride, methyltetrahydrophthalic anhydride, 3,6-endomethylenetetrahydrophthalic anhydride, methylendomethylenetetrahydrophthalic anhydride, tetrabromophthalic anhydride, and products obtained by reacting 9,10-dihydro-9-oxa-10-phosphaphenanthrene-10-oxide with itaconic anhydride or maleic anhydride; trimellitic anhydride; and aliphatic or aromatic tetrabasic acid dianhydrides such as biphenyltetracarboxylic dianhydride, naphthalenetetracarboxylic dianhydride, diphenylethertetracarboxylic dianhydride, butanetetracarboxylic dianhydride, cyclopentanetetracarboxylic dianhydride, pyromellitic anhydride, and benzophenonetetracarboxylic dianhydride. Preferred of these is tetrahydrophthalic anhydride.

These polybasic acid anhydrides may be used alone or in combination of two or more.

The polybasic acid anhydride to be reacted is preferably added in an amount of 0.1 to 1.1 mol per mole of the hydroxy groups in the reaction product obtained in the step (a-2). The amount is more preferably 0.15 to 1 mol, still more preferably 0.2 to 0.9 mol, most preferably 0.4 to 0.7 mol.

In the reaction in the step (a-3), a catalyst may be used if necessary. The catalyst used may be the same as the catalyst described above.

As for the reaction conditions of the step (a-3), the reaction temperature is preferably, but not limited to, 60° C. to 150° C., more preferably 70° C. to 135° C., still more preferably 80 to 120° C. The reaction time is preferably, but not limited to, 1 to 10 hours, more preferably 2 to 9 hours, still more preferably 3 to 8 hours.

The method for producing an alkali-soluble resin may include other steps in addition to the above-described reaction steps. Examples of the other steps include an aging step, a neutralization step, a dilution step, a drying step, a concentration step, and a purification step. These steps can be performed by known methods.

In the alkali-soluble resin obtained by the above-described method for producing an alkali-soluble resin, the amount of an ammonium salt compound is preferably 0.06% by mass or less, more preferably 0.03% by mass or less, still more preferably 0.01% by mass or less, most preferably 0% by mass, relative to 100% by mass of the alkali-soluble resin.

The production method can efficiently produce an alkali-soluble resin capable of providing a cured product having excellent heat discoloration resistance and a high refractive index.

The present invention encompasses such a method for producing an alkali-soluble resin, the method including: a step (a-1) of reacting a bisphenol compound with a bifunctional epoxy compound having a Gardner color scale based on JIS K 0071-2 of less than 12 and a melting point of 90° C. or higher; a step (a-2) of reacting a reaction product obtained in the step (a-1) with an unsaturated monobasic acid; and a step (a-3) of reacting a reaction product obtained in the step (a-2) with a polybasic acid anhydride, wherein the alkali-soluble resin obtained by the production method contains an ammonium salt compound in an amount of 0.06% by mass or less relative to 100% by mass of the alkali-soluble resin.

### 3. Alkali-Soluble Resin Composition

The present invention also relates to an alkali-soluble resin composition containing the alkali-soluble resin described above and an acid group-containing epoxy (meth)acrylate.

The alkali-soluble resin composition of the present invention containing the alkali-soluble resin described above can provide a cured product having excellent heat discoloration resistance and a high refractive index. The presence of an acid group-containing epoxy (meth)acrylate can improve the developability and curability and impart the properties derived from the acid group-containing epoxy (meth)acrylate skeleton.

The acid group-containing epoxy (meth)acrylate is an ester of an epoxy resin and (meth)acrylic acid, and is a compound containing an acid group.

To provide a cured product having improved crosslink density, the epoxy resin is preferably a bifunctional or higher functional epoxy resin, more preferably a bi- to 20 functional epoxy resin, still more preferably a bi- to 10 functional epoxy resin, most preferably a bifunctional epoxy resin.

The epoxy resin may be any compound having an epoxy group, and examples thereof include known aliphatic epoxy resins and aromatic epoxy resins. Preferred of these are aromatic epoxy resins because they can form a dense cured film and improve electrical insulation properties. One or two or more of these epoxy resins may be contained.

Examples of the aromatic epoxy resins include bisphenol A epoxy resin, bisphenol F epoxy resin, bisphenol S epoxy resin, biphenyl epoxy resin, tetramethylbiphenyl epoxy resin, phenol novolac epoxy resin, cresol novolac epoxy resin, bisphenol A novolac epoxy resin, triphenylmethane epoxy resin, tetraphenylethane epoxy resin, dicyclopentadiene-phenol addition reaction epoxy resin, phenol aralkyl epoxy resin, naphthol novolac epoxy resin, naphthol aralkyl epoxy resin, naphthol-phenol co-condensed novolac epoxy resin, naphthol-cresol co-condensed novolac epoxy resin, aromatic hydrocarbon formaldehyde resin-modified phenol resin-based epoxy resin, and biphenyl novolac epoxy resin. Preferred of these aromatic epoxy resins are bisphenol A epoxy resin and cresol novolac epoxy resin because they can achieve good electrical properties. More preferred is bisphenol A epoxy resin because it can provide a cured product having better heat discoloration resistance and a higher refractive index.

These epoxy resins may each have a substituent such as a halogen atom, an alkyl group, an alkylene group, a cycloalkylene group, an arylene group, or a cyano group.

The epoxy resin may have a molecular weight distribution. The epoxy resin preferably has a weight average molecular weight of 100 to 30000, more preferably 150 to 2000, still more preferably 300 to 1000.

The weight-average molecular weight is a value obtained by measurement using gel permeation chromatography (GPC).

The epoxy resin preferably has an epoxy equivalent of 150 to 5000 g/eq, more preferably 170 to 1000 g/eq, still more preferably 200 to 300 g/eq, to provide a cured product having excellent physical properties.

The epoxy equivalent can be determined by the method according to JIS K 7236:2001, specifically, by the method described in the EXAMPLES below.

Examples of the acid group include a carboxy group, a phenolic hydroxy group, a carboxylic anhydride group, a phosphoric acid group, and a sulfonic acid group. To achieve good developability, preferred of these is a carboxy group.

The acid group-containing epoxy (meth)acrylate may be an acid group-containing epoxy (meth)acrylate obtained by reacting a polybasic acid anhydride with epoxy (meth)acrylate that is obtained by reacting the epoxy resin with (meth)acrylic acid, or may be an acid group-containing epoxy (meth)acrylate obtained by reacting the acid group-containing epoxy resin with (meth)acrylic acid. To achieve excellent production efficiency of the alkali-soluble resin composition, the acid group-containing epoxy (meth)acrylate is preferably an acid group-containing epoxy (meth)acrylate obtained by reacting a polybasic acid anhydride with epoxy (meth)acrylate that is obtained by reacting the epoxy resin with (meth)acrylic acid.

By reacting the epoxy resin with (meth)acrylic acid, the epoxy group is ring-opened to generate a hydroxy group, and a structure in which a polybasic acid anhydride is added to the hydroxy group is formed.

Examples of the polybasic acid anhydride include the same anhydrides as the polybasic acid anhydrides described above.

The acid group-containing epoxy (meth)acrylate preferably has an acid value of 20 to 160 mgKOH/g, more preferably 30 to 150 mgKOH/g, still more preferably 40 to 140 mgKOH/g, most preferably 70 to 100 mgKOH/g.

In the alkali-soluble resin composition, the amount of the alkali-soluble resin is preferably 1 to 99% by mass, more preferably 5 to 95% by mass, still more preferably 10 to 90% by mass, most preferably 20 to 40% by mass, based on 100% by mass of a total amount of solids in the alkali-soluble resin composition. In the present invention, the total amount of solids means the total amount of components that form a cured product (excluding the curing catalyst and the solvent that volatilizes during the formation of the cured product, for example).

In the alkali-soluble resin composition, the amount of the acid group-containing epoxy (meth)acrylate is preferably 0.1 to 90% by mass, more preferably 1 to 85% by mass, still more preferably 5 to 80% by mass, most preferably 60 to 80% by mass, based on 100% by mass of a total amount of solids in the alkali-soluble resin composition.

As for the ratio of the amount of the acid group-containing epoxy (meth)acrylate to the amount of the alkali-soluble resin in the alkali-soluble resin composition, the amount of the acid group-containing epoxy (meth)acrylate relative to 100 parts by mass of the alkali-soluble resin is preferably 0.1 to 500 parts by mass, more preferably 10 to 400 parts by mass, still more preferably 100 to 300 parts by mass.

To achieve good developability, the alkali-soluble resin composition preferably has an acid value of 20 to 150 mgKOH/g, more preferably 30 to 135 mgKOH/g, further preferably 40 to 120 mgKOH/g, most preferably 70 to 100 mgKOH/g.

The acid value of the alkali-soluble resin composition can be determined by the same method as that for determining the double bond equivalent of the alkali-soluble resin.

The alkali-soluble resin composition preferably has a double bond equivalent of 300 to 2000 g/eq. To improve curability, the double bond equivalent is more preferably 330 to 1500 g/eq, still more preferably 360 to 1100 g/eq, further preferably 400 to 900 g/eq.

The double bond equivalent of the alkali-soluble resin composition can be determined by the same method as that for determining the double bond equivalent of the alkali-soluble resin.

The alkali-soluble resin composition may contain other components in addition to the above-described components, if necessary. Examples of the other components include solvents; colorants (pigments, dyes); dispersants; heat resistance improvers; leveling agents; developing aids; inorganic fine particles such as silica fine particles; silane coupling agents, aluminum coupling agents, and titanium coupling agents; fillers; thermosetting resins such as phenolic resins and polyvinylphenol; polymerizable compounds; curing aids such as polyfunctional thiol compounds; plasticizers; polymerization initiators; polymerization inhibitors; ultraviolet absorbers; antioxidants; matting agents; defoaming agents; antistatic agents; slip agents; surface modifiers; thixotropic agents; thixotropic aids; quinone diazide compounds; polyhydric phenol compounds; cationic polymerizable compounds; and thermal acid generators. These may be used alone or in combination of two or more. The other components can be appropriately selected from known components and the amounts used can be appropriately set.

In particular, the alkali-soluble resin composition preferably further contains at least one selected from the group consisting of a polymerizable compound, a polymerization initiator, and inorganic fine particles.

### (Polymerizable Compound)

The polymerizable compound is a low molecular weight compound having a polymerizable unsaturated bond (also referred to as a polymerizable unsaturated group) that is polymerizable by free radicals or irradiation with active energy rays such as electromagnetic waves (e.g., infrared rays, ultraviolet rays, X-rays) or electron beams. Examples of the polymerizable compound include a monofunctional compound having one polymerizable unsaturated group in the molecule and a polyfunctional compound having two or more polymerizable unsaturated groups in the molecule.

Examples of the monofunctional compound include N-substituted maleimide monomers; (meth)acrylic acid esters; (meth)acrylamides; unsaturated monocarboxylic acids; unsaturated polycarboxylic acids; unsaturated monocarboxylic acids in which the unsaturated groups and the carboxy groups are chain-extended; unsaturated acid anhydrides; aromatic vinyl compounds; conjugated dienes; vinyl esters; vinyl ethers; N-vinyl compounds; and unsaturated isocyanates. Furthermore, monomers having an active methylene group or an active methine group can also be used, for example.

Examples of the polyfunctional compound are listed as follows:
ethylene glycol di(meth)acrylate, diethylene glycol di(meth)acrylate, polyethylene glycol di(meth)acrylate, propylene glycol di(meth)acrylate, butylene glycol di(meth)acrylate, hexanediol di(meth)acrylate, cyclohexanedimethanol di(meth)acrylate, bisphenol A alkylene oxide di(meth)acrylates, bisphenol F alkylene oxide di(meth)acrylates, and other bifunctional (meth)acrylate compounds;
trimethylolpropane tri(meth)acrylate, ditrimethylolpropane tetra(meth)acrylate, glycerin tri(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, ethylene oxide-added trimethylolpropane tri(meth)acrylate, ethylene oxide-added ditrimethylolpropane tetra(meth)acrylate, ethylene oxide-added pentaerythritol tetra(meth)acrylate, ethylene oxide-added dipentaerythritol hexa(meth)acrylate, propylene oxide-added trimethylolpropane tri(meth)acrylate, propylene oxide-added ditrimethylolpropane tetra(meth)acrylate, propylene oxide-added pentaerythritol tetra(meth)acrylate, propylene oxide-added dipentaerythritol hexa(meth)acrylate, ε-caprolactone-added trimethylolpropane tri(meth)acrylate, ε-caprolactone-added ditrimethylolpropane tetra(meth)acrylate, ε-caprolactone-added pentaerythritol tetra(meth)acrylate, ε-caprolactone-added dipentaerythritol hexa(meth)acrylate, a succinic acid-modified dipentaerythritol pentaacrylate, a succinic acid-modified pentaerythritol triacrylate, a phthalic acid-modified dipentaerythritol pentaacrylate, a phthalic acid-modified pentaerythritol triacrylate, a modified dipentaerythritol hexaacrylate represented by the following formula:

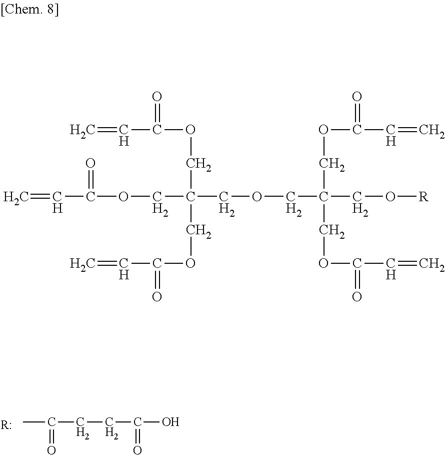

and other tri- or higher functional (meth)acrylate compounds;
ethylene glycol divinyl ether, diethylene glycol divinyl ether, polyethylene glycol divinyl ether, propylene glycol divinyl ether, butylene glycol divinyl ether, hexanediol divinyl ether, bisphenol A alkylene oxide divinyl ethers, bisphenol F alkylene oxide divinyl ethers, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, ethylene oxide-added trimethylolpropane trivinyl ether, ethylene oxide-added ditrimethylolpropane tetravinyl ether, ethylene oxide-added pentaerythritol tetravinyl ether, ethylene oxide-added dipentaerythritol hexavinyl ether, and other polyfunctional vinyl ethers;
2-vinyloxyethyl (meth)acrylate, 3-vinyloxypropyl (meth)acrylate, 1-methyl-2-vinyloxyethyl (meth)acrylate, 2-vinyloxypropyl (meth)acrylate, 4-vinyloxybutyl (meth)acrylate, 4-vinyloxycyclohexyl (meth)acrylate, 5-vinyloxypentyl (meth)acrylate, 6-vinyloxyhexyl (meth)acrylate, 4-vinyloxymethylcyclohexylmethyl (meth)acrylate, p-vinyloxymethylphenylmethyl (meth)acrylate, 2-(vinyloxyethoxy)ethyl (meth)acrylate, 2-(vinyloxyethoxyethoxyethoxy)ethyl (meth)acrylate, and other vinyl ether group-containing (meth)acrylic acid esters;
ethylene glycol diallyl ether, diethylene glycol diallyl ether, polyethylene glycol diallyl ether, propylene glycol diallyl ether, butylene glycol diallyl ether, hexanediol diallyl ether, bisphenol A alkylene oxide diallyl ethers, bisphenol F alkylene oxide diallyl ethers, trimethylolpropane triallyl ether, ditrimethylolpropane tetraallyl ether, glycerin triallyl ether, pentaerythritol tetraallyl ether, dipentaerythritol pentaallyl ether, dipentaerythritol hexaallyl ether, ethylene oxide-added trimethylolpropane triallyl ether, ethylene oxide-added ditrimethylolpropane tetraallyl ether, ethylene oxide-added pentaerythritol tetraallyl ether, ethylene oxide-added dipentaerythritol hexaallyl ether, and other polyfunctional allyl ethers;
allyl group-containing (meth)acrylic acid esters such as allyl (meth)acrylate; polyfunctional (meth)acryloyl group-containing isocyanurates such as tri(acryloyloxyethyl)isocyanurate, tri(methacryloyloxyethyl)isocyanurate, alkylene oxide-added tri(acryloyloxyethyl)isocyanurates, and alkylene oxide-added tri(methacryloyloxyethyl)isocyanurates;
polyfunctional allyl group-containing isocyanurates such as triallyl isocyanurate; polyfunctional urethane (meth)acrylates obtained by reacting a polyfunctional isocyanate such as tolylene diisocyanate, isophorone diisocyanate, or xylylene diisocyanate with a hydroxy group-containing (meth)acrylic acid ester such as 2-hydroxyethyl (meth)acrylate or 2-hydroxypropyl (meth)acrylate; and polyfunctional aromatic vinyl compounds such as divinylbenzene. These polymerizable compounds may be used alone or in combination of two or more.

The polymerizable compound is preferably a polyfunctional polymerizable compound to provide a curable resin composition having more improved curability. The number of functional groups of the polyfunctional polymerizable compound is preferably 3 or more, more preferably 4 or more. The number of functional groups is preferably 10 or less, more preferably 8 or less.

The polymerizable compound may have any molecular weight. The molecular weight is preferably, for example, 2000 or less in terms of handling.

In terms of reactivity, economic efficiency, availability, and the like, the polyfunctional polymerizable compound is preferably a compound having a (meth)acryloyl group, such as a polyfunctional (meth)acrylate compound, a polyfunctional urethane (meth)acrylate compound, or a (meth)acryloyl group-containing isocyanurate compound, more preferably a polyfunctional (meth)acrylate compound. The presence of a compound having a (meth)acryloyl group can provide a curable resin composition having better photosensitivity and curability, which can provide a cured product having even higher hardness and transparency. The polyfunctional polymerizable compound is still more preferably a tri- or higher functional (meth)acrylate compound.

The amount of the polymerizable compound is preferably 0 to 500 parts by mass, more preferably 5 to 300 parts by mass, still more preferably 10 to 100 parts by mass, relative to 100 parts by mass of the alkali-soluble resin (solids).

### (Polymerization Initiator)

The polymerization initiator is preferably a photopolymerization initiator, more preferably a radically polymerizable polymerization initiator.

Specific examples of the photopolymerization initiator include aminoketone compounds such as 2-methyl-1-[4-(methylthio)phenyl]-2-morpholinopropan-1-one (“Irgacure 907”, available from BASF), 2-benzyl-2-dimethylamino-1-(4-morpholinophenyl)-butanone-1 (“Irgacure 369”, available from BASF), and 2-dimethylamino-2-(4-methyl-benzyl)-1-(4-morpholin-4-yl-phenyl)-butan-1-one (“Irgacure 379”, available from BASF); benzyl ketal compounds such as 2,2-dimethoxy-1,2-diphenylethan-1-one (“Irgacure 651”, available from BASF) and phenylglyoxylic acid methyl ester (“Darocur MBF, available from BASF); hydroketone compounds such as 1-hydroxy-cyclohexyl-phenyl-ketone (“Irgacure 184”, available from BASF), 2-hydroxy-2-methyl-1-phenyl-propan-1-one (“Darocur 1173”, available from BASF), 1-[4-(2-hydroxyethoxy)-phenyl]-2-hydroxy-2-methyl-1-propan-1-one (“Irgacure 2959”, available from BASF), 2-hydroxy-1-{4-[4-(2-hydroxy-2-methyl-propionyl)-benzyl]-phenyl}-2-methyl-propan-1-one (“Irgacure 127”, available from BASF), [1-hydroxy-cyclohexyl-phenyl-ketone+benzophenone](“Irgacure 500”, available from BASF); other alkylphenone compounds exemplified in paragraphs [0084] to [0086] of JP 2013-227485 A; oxime ester compounds such as 1,2-octanedione, 1-[4-(phenylthio)phenyl]-, 2-(O-benzoyloxime) (“OXE01”, available from BASF), ethanone, 1-[9-ethyl-6-(2-methylbenzoyl)-9H-carbazol-3-yl]-, 1-(O-acetyloxime) (“OXE02”, available from BASF), 1,2-octanedione, 1-[4-(phenylthio)-, 2-, (O-benzoyloxime)], ethanone (“OXE03”, available from BASF), 1-[9-ethyl-6-(2-methylbenzoyl)-9H-carbazol-3-yl]-, 1-(0-acetyloxime) (“OXE04”, available from BASF); benzophenone compounds; benzoin compounds; thioxanthone compounds; halomethylated triazine compounds; halomethylated oxadiazole compounds; biimidazole compounds; titanocene compounds; benzoic acid ester compounds; acridine compounds; and phosphine oxide compounds. Preferred of these are aminoketone compounds and oxime ester compounds. These photopolymerization initiators may be used alone or in combination of two or more.

The amount of the polymerization initiator is preferably 0 to 20% by mass, more preferably 0.3 to 15% by mass, still more preferably 0.5 to 10% by mass, further preferably 1 to 10% by mass, based on 100% by mass of a total amount of solids in the alkali-soluble resin composition.

### (Inorganic Fine Particles)

Examples of the inorganic fine particles include the inorganic particles described in JP 2018-119086 A. In particular, the inorganic fine particles are preferably metal particles or metal oxide particles, more preferably metal oxide particles.

Examples of the inorganic fine particles include metal particles or metal oxide particles containing a light-transmitting metal element having a high refractive index, such as Be, Mg, Ca, Sr, Ba, Sc, Y, La, Ce, Gd, Tb, Dy, Yb, Lu, Ti, Zr, Hf, Nb, Mo, W, Zn, B, Al, Si, Ge, Sn, Pb, Sb, Bi, or Te. In particular, the inorganic fine particles preferably contain at least one metal element selected from the group consisting of Ti, Al, Zr, Zn, Sn, Ce, Nb, and Si to provide a cured product having a higher refractive index, more preferably contain Zr to provide a cured film having a high dielectric constant, more preferably contain Si to provide a cured film having high hardness.

The metal oxide may be a single metal oxide, a solid solution of two or more oxides, or a complex oxide. Examples of the single metal oxide include aluminum oxide (Al₂O₃), titanium oxide (TiO₂), zirconium oxide (ZrO₂), indium oxide (In₂O₃), zinc oxide (ZnO), tin oxide (SnO₂), lanthanum oxide (La₂O₃), yttrium oxide (Y₂O₃), cerium oxide (CeO₂), magnesium oxide (MgO), silicon oxide (SiO₂), and niobium oxide (Nb₂O₅). Examples of the solid solution of two or more oxides include ITO and ATO. Examples of the complex oxide include barium titanate (BaTiO₃), perovskite (CaTiO₃), and spinel (MgAl₂O₄).

To provide a cured product having a high refractive index and a high dielectric constant or a high hardness, preferred of these inorganic fine particles are zirconium dioxide particles (ZrO₂ particles) and/or silicon dioxide particles (SiO₂ particles)

The inorganic fine particles may or may not be surface-modified. To enhance the dispersibility in the resin composition, the inorganic fine particles are preferably surface-modified. The surfaces of the inorganic fine particles can be made lipophilic through surface modification, preventing agglomeration of the particles and enabling fine dispersion of the particles.

When the inorganic fine particles are surface-modified, the mass of the inorganic fine particles includes the mass of the surface modifier. The organic compound (surface modifier) that modifies the surfaces of the inorganic fine particles may be either chemically bonded and/or coordinated to the inorganic fine particles or attached to the inorganic fine particles by hydrogen bonding or salt formation. The phrase “surface-modified/surface modification” includes both a state where the organic group is chemically bonded and/or coordinated to the inorganic fine particles and the like, and a state where the organic group is physically attached to the inorganic fine particles and the like.

The surface-modified inorganic fine particles (hereinafter also referred to as “coated inorganic fine particles”) can be obtained by a known method, such as a method of mixing the inorganic fine particles and a surface modifier in a solvent or a method of carrying out a hydrothermal reaction in the presence of water.

In the method of mixing the inorganic fine particles and a surface modifier in a solvent, the surface modifier used may be any organic compound that can make the surfaces of the inorganic fine particles lipophilic, prevent the particles from agglomeration, and finely disperse the particles. Examples thereof include an organic acid, a coupling agent, and a surfactant. These may be used alone or in combination of two or more.

Preferred examples of the organic acid include carboxylic acids (compounds having a carboxy group) having five or more carbon atoms. Specific examples of the carboxylic acids include pentanoic acid, hexanoic acid, heptanoic acid, octanoic acid, nonanoic acid, 2-ethylhexanoic acid, 2-methylheptanoic acid, 4-methyloctanoic acid, salicylic acid, naphthenic acid, decanoic acid, undecylic acid, neodecanoic acid, lauric acid, tridecylic acid, myristic acid, pentadecylic acid, palmitic acid, heptadecylic acid, pivalic acid, 2,2-dimethylbutyric acid, 3,3-dimethylbutyric acid, 2,2-dimethylvaleric acid, 2,2-diethylbutyric acid, 3,3-diethylbutyric acid, stearic acid, pristanic acid, 2-acryloyloxyethyl hexahydrophthalic acid, 2-methacryloyloxyethyl hexahydrophthalic acid, acrylic acid, methacrylic acid, half esters of C3-C9 aliphatic dicarboxylic acids with (meth)acryloyloxy C1-C6 alkyl alcohols, such as 2-acryloyloxyethyl succinic acid and 2-methacryloyloxyethyl succinic acid; and half esters of C8-C14 aromatic dicarboxylic acids with (meth)acryloyloxy C1-C6 alkyl alcohols, such as 2-acryloyloxyethyl phthalic acid and 2-methacryloyloxyethyl phthalic acid. These organic acids may be used alone or in combination of two or more.

An example of the coupling agent is a compound having an organic group capable of forming a bond with the inorganic fine particles and a reactive functional group capable of making the particles lipophilic. Examples of the reactive functional group include a (meth)acryloyloxy group, an epoxy group, an amino group, a vinyl group, a thiol group, an acid anhydride group, and a phenol group. The inorganic fine particles surface-treated with a compound having any of the reactive functional groups can have reactive functional groups derived from the coupling agent, such as a (meth)acryloyloxy group, an epoxy group, an amino group, a vinyl group, a thiol group, an acid anhydride group, and a phenol group, on the surfaces. These coupling agents may be used alone or in combination of two or more.

Examples of the coupling agent include a silane coupling agent, a titanate coupling agent, and an aluminate coupling agent.

Examples of the silane coupling agent include (meth)acryloyloxy silane coupling agents such as 3-(meth)acryloyloxypropylmethyldimethoxysilane, 3-(meth)acryloyloxypropyltrimethoxysilane, 3-(meth)acryloyloxypropylmethyldiethoxysilane, and 3-(meth)acryloyloxypropyltriethoxysilane; epoxy silane coupling agents such as diethoxy(glycidyloxypropyl)methylsilane, 2-(3,4-epoxycyclohexyl)ethyltrimethoxysilane, 3-glycidoxypropyltrimethoxysilane, 3-glycidoxypropylmethyldiethoxysilane, and 3-glycidoxypropyltriethoxysilane; and amino silane coupling agents such as N-2-(aminoethyl)-3-aminopropylmethyldimethoxysilane, N-2-(aminoethyl)-3-aminopropyltrimethoxysilane, N-2-(aminoethyl)-3-aminopropyltriethoxysilane, 3-aminopropyltrimethoxysilane, 3-aminopropyltriethoxysilane, 3-triethoxysilyl-N-(1,3-dimethyl-butylidene)propylamine, and N-phenyl-3-aminopropyltrimethoxysilane.

Examples of the titanate coupling agent include isopropyl triisostearoyl titanate, isopropyl dimethacryl isostearoyl titanate, isopropyl tri(dodecyl)benzenesulfonyl titanate, neopentyl(diallyl)oxy-tri(dioctyl)phosphate titanate, and neopentyl(diallyl)oxy-trineododecanoyl titanate.

An example of the aluminate coupling agent is acetoalkoxyaluminum diisopropylate.

Examples of the surfactant include ionic surfactants such as an anionic surfactant, a cationic surfactant, and a zwitterionic surfactant and nonionic surfactants. These surfactants may be used alone or in combination of two or more.

Examples of the anionic surfactant include fatty acid surfactants such as fatty acid sodium salts (e.g., sodium oleate, sodium stearate, sodium laurate), fatty acid potassium salts, and sodium fatty acid ester sulfonate; phosphate surfactants such as alkyl phosphoric acids, alkyl phosphate esters, and sodium alkyl phosphate esters; olefin surfactants such as sodium alpha olein sulfonate; alcohol surfactants such as sodium alkyl sulfates; and alkylbenzene surfactants.

Examples of the cationic surfactant include alkylmethylammonium chlorides, alkyldimethylammonium chlorides, alkyltrimethylammonium chlorides, and alkyldimethylbenzylammonium chlorides.

Examples of the zwitterionic surfactant include carboxylate surfactants such as alkylaminocarboxylates, and phosphate ester surfactants such as phosphobetaine.

Examples of the nonionic surfactants include fatty acid surfactants such as polyoxyethylene lanolin fatty acid esters and polyoxyethylene sorbitan fatty acid esters; polyoxyethylene alkyl phenyl ethers; fatty acid alkanolamides; and phosphate surfactants such as organic phosphate esters, alkyl phosphate esters, phosphate polyesters, and polyoxyalkylene alkyl ether phosphate esters.

The inorganic fine particles and the surface modifier may be mixed in a solvent. When the inorganic fine particles and the surface modifier are mixed in a solvent, the inorganic fine particles in powder form may be added to and mixed with a dispersion of the surface modifier, the surface modifier may be added to and mixed with a dispersion (slurry) of the inorganic fine particles, or the dispersions thereof prepared may be mixed.

For example, when a dispersion of zirconium oxide (ZrO₂) particles is prepared, the amount of the dispersion medium used is preferably an amount capable of sufficiently dispersing the zirconium oxide particles. The total amount of the dispersion medium is preferably 20 parts by mass or more, more preferably 40 parts by mass or more, still more preferably 60 parts by mass or more, while preferably 600 parts by mass or less, more preferably 550 parts by mass or less, still more preferably 500 parts by mass or less, relative to 100 parts by mass of the zirconium oxide particles.

Non-limiting examples of the solvent (dispersion medium) used during the mixing and the solvent used in the dispersion include water; alcohols such as methanol, ethanol, propanol, 2-propanol (IPA), butanol, diacetone alcohol, furfuryl alcohol, and tetrahydrofurfuryl alcohol; esters such as methyl acetate, ethyl acetate, isopropyl acetate, propyl acetate, isobutyl acetate, butyl acetate, isopentyl acetate, pentyl acetate, 3-methoxybutyl acetate, 2-ethylbutyl acetate, cyclohexyl acetate, and ethylene glycol monoacetate; glycols such as ethylene glycol and hexylene glycol; ethers such as diethyl ether, ethylene glycol monomethyl ether, ethylene glycol monoethyl ether, ethylene glycol monobutyl ether, ethylene glycol isopropyl ether, diethylene glycol monomethyl ether, diethylene glycol monoethyl ether, propylene glycol monomethyl ether, and propylene glycol monoethyl ether; ketones such as acetone, methyl ethyl ketone, methyl isobutyl ketone, butyl methyl ketone, cyclohexanone, methylcyclohexanone, dipropyl ketone, methyl pentyl ketone, and diisobutyl ketone; and toluene. These may be used alone or in combination of two or more.

The mixing ratio of the inorganic fine particles and the surface modifier is not limited and can be appropriately set from known methods. For example, when a (silane) coupling agent is used as the surface modifier, the amount of the (silane) coupling agent used is preferably 0.01 to 100 parts by mass, more preferably 1 to 70 parts by mass, still more preferably 1 to 40 parts by mass, relative to 100 parts by mass of the inorganic fine particles.

The temperature at which the inorganic fine particles and the surface modifier are mixed in a solvent may be appropriately selected from known methods. After mixing, the mixture may be reacted by heating, if necessary.

The coated inorganic fine particles can also be obtained by a method of carrying out a hydrothermal reaction in the presence of water. An example of the method for carrying out a hydrothermal reaction in the presence of water is a method in which a compound that produces coated inorganic fine particles through a hydrothermal reaction is heated in the presence of water.

Examples of the compound that produces coated inorganic fine particles through a hydrothermal reaction include various coated inorganic fine particle precursors, such as hydroxides, chlorides, oxychlorides, sulfates, acetates, organic acid salts, and alkoxides of various metals, as well as salts of various metals and carboxylic acids.

Specific examples of the compound that produces coated inorganic fine particles through a hydrothermal reaction include compounds containing zirconium such as zirconium hydroxide, zirconium chloride, zirconium oxychloride, zirconium oxyacetate, zirconium oxynitrate, zirconium sulfate, zirconium octanoate, zirconium 2-ethylhexanoate, zirconium oxide oleate, zirconium acetate, zirconium oxide stearate, zirconium oxide laurate, and zirconium alkoxides (e.g., zirconium tetrabutoxide). Examples also include compounds containing titanium such as titanium hydroxide, titanium chloride, titanium oxychloride, titanium oxyacetate, titanium oxynitrate, titanium sulfate, titanium octanoate, titanium oxide oleate, titanium acetate, titanium oxide stearate, titanium oxide laurate, titanium alkoxides such titanium tetrabutoxide (e.g., tetra-n-butoxytitanium). For example, when zirconium 2-ethylhexanoate is subjected to a hydrothermal reaction, zirconium oxide coated with 2-ethylhexanoic acid and/or a carboxylic acid derived from 2-ethylhexanoic acid can be obtained.

The reaction conditions of the hydrothermal reaction, such as the amount of water used, the reaction temperature, and the reaction time, are not limited and can be appropriately selected from known methods.

The coated inorganic fine particles obtained by the hydrothermal reaction may be further treated with any of the above-described surface modifiers (organic acids, coupling agents, surfactants). The method for treatment with the surface treatment agent may be the same as the above-described method for surface-modifying the inorganic fine particles with the surface modifier.

The coated inorganic fine particles have an affinity for organic solvents because their surfaces are modified with reactive functional groups. Such inorganic fine particles are stably dispersed in the form of nanoparticles in any of the above-described various organic solvents. Specifically, such a dispersion can be handled in a highly transparent solution state. Typically, the coated inorganic fine particles may be used in the form of a dispersion in which the inorganic fine particles are dispersed in the surface modifying liquid used for surface modification, or may be used in the form of a powder obtained by distilling off the solvent under reduced pressure.

The amount of the surface modifier in the coated inorganic fine particles is preferably 0 to 50 parts by mass, more preferably 1 to 40 parts by mass, still more preferably 2 to 30 parts by mass, relative to 100 parts by mass of the inorganic fine particles. When the amount of the surface modifier falls within the above range, the alkali-soluble resin composition of the present invention can have a higher refractive index and also can have improved properties such as hardness and relative dielectric constant.

Examples of the shape of the inorganic fine particles (including coated inorganic fine particles, the same applies below) include a spherical shape, an ellipsoidal shape, a cubic shape, a rectangular shape, a pyramidal shape, a needle shape, a cylindrical shape, a rod-like shape, a tubular shape, a scaly shape, a plate-like shape, and a flaky shape. Considering the dispersibility in a solvent, the shape is preferably a spherical shape, a cylindrical shape, or the like.

The inorganic fine particles preferably have a crystallite size of 20 nm or less. When the crystallite size of the inorganic fine particles falls within the above-described range, a curable resin composition containing the inorganic fine particles can have improved transparency. The crystallite size is more preferably 15 nm or less, still more preferably 10 nm or less. The lower limit of the crystallite size is usually about 1 nm. In other words, the crystallite size is preferably 1 to 20 nm, more preferably 1 to 15 nm, still more preferably 1 to 10 nm. The crystallite size can be calculated by X-ray diffraction analysis.

The inorganic fine particles preferably have a number average primary particle size of less than 30 nm, more preferably 25 nm or less. When the number average primary particle size of the inorganic fine particles falls within the above-described range, a resin composition containing the inorganic fine particles can have improved transparency. The number average primary particle size is more preferably 20 nm or less, still more preferably 15 nm or less. The lower limit of the number average primary particle size is preferably more than 1 nm, more preferably 3 nm or more, still more preferably 5 nm or more. In other words, the number average primary particle size is preferably more than 1 nm and less than 30 nm, more preferably 3 to 25 nm, still more preferably 5 to 20 nm. It is further preferably 5 to 15 nm.

The number average primary particle size can be determined as follows: the inorganic fine particles are observed under magnification with a microscope such as a transmission electron microscope (TEM), a field emission transmission electron microscope (FE-TEM), or a field emission scanning electron microscope (FE-SEM); 100 particles are randomly selected from the particles and subjected to measurement of the lengths in the major axis direction; and the arithmetic means of the lengths is calculated.

The refractive index of the inorganic fine particles is preferably, but not limited to, 1.70 to 2.70, more preferably 1.90 to 2.70 to achieve a high refractive index. The refractive index is a refractive index for NaD line (589 nm) and can be determined by the method described in the EXAMPLES below.

The inorganic fine particles preferably have a specific surface area of 10 to 400 m²/g, more preferably 20 to 200 m²/g, most preferably 30 to 150 m²/g.

The amount of the inorganic fine particles is preferably 0 to 95% by mass, more preferably 5 to 90% by mass, still more preferably 10 to 80% by mass, further preferably 20 to 70% by mass, based on 100% by mass of a total amount of solids in the alkali-soluble resin composition.

The alkali-soluble resin composition may be produced by mixing the alkali-soluble resin and the acid group-containing epoxy (meth)acrylate by a known method. Alternatively, a composition containing the alkali-soluble resin and the acid group-containing epoxy (meth)acrylate can be efficiently produced by the production method described below. The following describes a preferred method for producing the alkali-soluble resin composition.

### 4. Method for Producing Alkali-Soluble Resin Composition

A preferred method for producing the alkali-soluble resin composition includes: a step (b-1) of reacting a bisphenol compound with a bifunctional epoxy compound having a Gardner color scale based on JIS K 0071-2 of less than 12 and a melting point of 90° C. or higher; a step (b-2) of adding an epoxy resin to a reaction product obtained in the step (b-1); a step (b-3) of reacting a mixture obtained in the step (b-2) with an unsaturated monobasic acid; and a step (b-4) of reacting a reaction mixture obtained in the step (b-3) with a polybasic acid anhydride.

Step (b-1)

The step (b-1) may be the same as the step (a-1) in the section “2. Method for producing alkali-soluble resin” described above.

Step (b-2)

The step (b-2) is a step of adding an epoxy resin to the reaction product obtained in the step (b-1). The addition of an epoxy resin can provide properties derived from the epoxy resin skeleton to a cured product of the resulting alkali-soluble resin composition.

Preferred examples of the epoxy resin include the epoxy resins listed above as starting materials for the acid group-containing epoxy (meth)acrylate.

These epoxy resins may be used alone or in combination of two or more.

The amount of the epoxy resin added is preferably 1 to 1000 parts by mass, more preferably 100 to 500 parts by mass, still more preferably 200 to 300 parts by mass, relative to 100 parts by mass of the bifunctional epoxy compound used in the step (b-1).

Step (b-3)

The step (b-3) is a step of reacting the mixture obtained in the step (b-2) with an unsaturated monobasic acid. In this reaction, the unsaturated monobasic acid reacts with the epoxy groups of the reaction product obtained in the step (b-1) in the mixture and with the epoxy groups of the epoxy resin, thereby introducing radically polymerizable unsaturated bonds into the reaction product and the epoxy resin. Thus, the reaction in the step (b-3) can produce a mixture of a compound in which radically polymerizable unsaturated bonds have been introduced into the reaction product obtained in the step (b-1) and a compound in which radically polymerizable unsaturated bonds have been introduced into the epoxy resin.

Examples of the unsaturated monobasic acid include the unsaturated monobasic acids described in the section “2. Method for producing alkali-soluble resin” described above.

The unsaturated monobasic acid to be reacted in the step (b-3) is preferably added in an amount such that the acid groups in the unsaturated monobasic acid is 0.6 to 1.4 mol per mole of the epoxy groups in the mixture obtained in the step (b-2). The amount is more preferably 0.7 to 1.3 mol, still more preferably 0.8 to 1.2 mol, most preferably 1.0 to 1.1 mol. If epoxy groups remain, the storage stability may deteriorate.

To reduce the acid concentration in the reaction system, the unsaturated monobasic acid is preferably added in several portions or added sequentially in small portions, rather than adding it all at once. If the acid concentration in the reaction system increases, a dehydration condensation reaction with the hydroxy groups generated as a by-product by the reaction between the acid and the epoxy may occur simultaneously, or thermal polymerization between the acids may proceed.

In the reaction in the step (b-3), a catalyst is preferably used.

Examples of the catalyst include the catalysts described in the section “2. Method for producing alkali-soluble resin” described above.

In the reaction in the step (a-3), a total amount of the catalyst may be added all at once or may be added in portions, and is preferably added in portions. By adding the catalyst in portions, deactivation of the catalyst can be compensated and a decrease in catalytic activity can be prevented or reduced. If a large amount of phosphine is used in the early stage in anticipation of deactivation of the catalyst, a resin with increased discoloration may be obtained because the oxidized phosphine is yellowish.

Examples of the method for adding the catalyst in portions include the same method as in the section “2. Method for producing alkali-soluble resin” described above.

In the reaction in the step (b-3), a polymerization inhibitor may be used.

Examples of the polymerization inhibitor include the polymerization inhibitors described in the section “2. Method for producing alkali-soluble resin” described above.

Non-limiting preferred examples of the reaction conditions of the step (b-3) include the same conditions as the conditions of the reaction with the unsaturated monobasic acid in the step (a-2) described in the section “2. Method for producing alkali-soluble resin” described above.

Step (b-4)

The step (b-4) is a step of reacting the reaction mixture obtained in the step (b-3) with a polybasic acid anhydride. In the step (b-4), a polybasic acid anhydride is added to the hydroxy groups of the reaction mixture obtained in the step (b-3) to introduce an acid group such as a carboxy group into the reaction mixture.

Examples of the polybasic acid anhydride include the polybasic acid anhydrides described in the section “2. Method for producing alkali-soluble resin” described above.

The polybasic acid anhydride to be reacted in the step (b-4) is preferably added in an amount of 0.1 to 1.1 mol per mole of the hydroxy groups in the reaction mixture obtained in the step (b-3). The amount is more preferably 0.15 to 1 mol, still more preferably 0.2 to 0.9 mol, most preferably 0.4 to 0.6 mol.

Non-limiting preferred examples of the reaction conditions of the step (b-4) include the same conditions as the conditions of the reaction with the polybasic acid anhydride in the step (a-3) described in the section “2. Method for producing an alkali-soluble resin” described above.

The method for producing an alkali-soluble resin composition may include other steps in addition to the above-described reaction steps. Examples of the other steps include an aging step, a neutralization step, a dilution step, a drying step, a concentration step, and a purification step. These steps can be performed by known methods.

The alkali-soluble resin composition obtained by the production method contains an ammonium salt compound in an amount of 0.06% by mass or less relative to 100% by mass of the alkali-soluble resin represented by the formula (1). The alkali-soluble resin composition in which the amount of the ammonium salt compound falls within the above range can provide a cured product having excellent heat discoloration resistance.

In the alkali-soluble resin composition, the amount of the ammonium salt compound is more preferably 0.03% by mass or less, still more preferably 0.01% by mass or less, most preferably 0% by mass, relative to 100% by mass of the alkali-soluble resin.

The present invention also encompasses such a method for producing the alkali-soluble resin composition, including: a step (b-1) of reacting a bisphenol compound with a bifunctional epoxy compound having a Gardner color scale based on JIS K 0071-2 of less than 12 and a melting point of 90° C. or higher; a step (b-2) of adding an epoxy resin to a reaction product obtained in the step (b-1); a step (b-3) of reacting a mixture obtained in the step (b-2) with an unsaturated monobasic acid; and a step (b-4) of reacting a reaction mixture obtained in the step (b-3) with a polybasic acid anhydride, wherein the alkali-soluble resin composition obtained by the production method contains an ammonium salt compound in an amount of 0.06% by mass or less relative to 100% by mass of the alkali-soluble resin.

### (Curing Method)

The alkali-soluble resin or alkali-soluble resin composition of the present invention may be cured to obtain a cured product by any known method. For example, the alkali-soluble resin composition is applied to a substrate or molded, and then cured by heating, irradiation with active energy rays such as ultraviolet rays, or a combination of these to obtain a cured product.

Preferably, the alkali-soluble resin composition is cured, for example, by a method including a step (1) of applying the alkali-soluble resin composition to a substrate to form a coating film, a step (2) of irradiating the formed coating film with light, a step (3) of developing and removing an unirradiated area, and a step (4) of heating an irradiated area of the coating film.

The substrate is not limited and may be appropriately selected depending on the purpose and application. Examples thereof include substrates made of various materials such as a glass plate and a plastic plate.

In the step (1), the method for applying the alkali-soluble resin composition to form a coating film is not limited and may be performed by a known method such as spin coating, slit coating, roll coating, or cast coating.

In the curing method, preferably, the alkali-soluble resin composition is applied to a substrate and the applied composition is then dried to form a coating film. The drying can be performed by a known method, for example, using a hot plate, an IR oven, a convection oven, or the like. The conditions of the drying are appropriately selected depending on the boiling point of the solvent component contained, the type of curable component, the film thickness, the performance of the dryer, and the like. Typically, the drying is preferably performed at a temperature of 50° C. to 160° C. for 10 to 300 seconds.

In the step (2), irradiation of the formed coating film with light may be performed by any method, and can be performed by a known method. Examples of a light source of actinic rays used for light irradiation include lamp light sources such as xenon lamps, halogen lamps, tungsten lamps, high-pressure mercury lamps, ultra-high-pressure mercury lamps, metal halide lamps, medium-pressure mercury lamps, low-pressure mercury lamps, carbon arcs, and fluorescent lamps; and laser light sources such as argon ion lasers, YAG lasers, excimer lasers, nitrogen lasers, helium cadmium lasers, and semiconductor lasers.

When the coating film is irradiated with light, the light irradiation may be performed through a photomask. The photomask may be a mask in which light-shielding portions are formed according to a desired pattern.

After the light irradiation, in the step (3), development is performed using a developer to remove unirradiated areas. Areas irradiated with light are cured, and the cured product becomes insoluble or poorly soluble in a developer. On the other hand, the unirradiated areas are dissolved in a developer and are thus removed by development, providing a patterned cured film. The development can be performed typically at a development temperature of 10° C. to 50° C. by a method such as immersion development, spray development, brush development, or ultrasonic development.

The developer used in the step (3) may be any developer that dissolves the alkali-soluble resin composition. The developer is typically an organic solvent, an alkaline aqueous solution, or may be a mixture of these. When the developer is an alkaline aqueous solution, it is preferably rinsed with water after development. Examples of the organic solvent and alkaline aqueous solution include those described in JP 2015-157909 A.

In the step (4), the coating film after development is heated at 260° C. or lower. The heating temperature in the heating step after the light irradiation in the step (4) (post-curing step) is preferably 260° C. or lower, more preferably 200° C. or lower. To maintain the curability, the lower limit of the heating temperature is preferably 70° C. or higher, more preferably 90° C. or higher.

The heating time in the heating step is preferably, but not limited to, 5 to 60 minutes, for example. The heating may be performed by any method and can be performed using known heating equipment such as a hot plate, a convection oven, or a high-frequency heater.

When the cured product obtained by the above-described curing method is a cured film, the cured film preferably has a film thickness of 0.1 to 50 μm, more preferably 0.5 to 40 μm, still more preferably 1 to 30 μm, to efficiently exhibit the properties as a protective film.

The cured film preferably has a b* value of 6.0 or less, more preferably 5.5 or less, in a heat discoloration resistance test. The heat discoloration resistance test is an evaluation test of heat discoloration resistance performed by the method described in the EXAMPLES below.

### 5. Applications

The alkali-soluble resin and alkali-soluble resin composition of the present invention can provide a cured product having excellent heat discoloration resistance and a high refractive index, and therefore can be suitably used in applications requiring heat discoloration resistance and a high refractive index. Furthermore, the alkali-soluble resin and alkali-soluble resin composition of the present invention have a high development speed and can be suitably used in applications requiring developability. Furthermore, the alkali-soluble resin and alkali-soluble resin composition of the present invention have a good voltage holding ratio and can thus be suitably used in applications requiring such a voltage holding ratio.

The alkali-soluble resin and alkali-soluble resin composition of the present invention can be widely used in various applications such as magnetic recording materials, catalyst materials, ultraviolet absorbing materials, dental materials, contact lenses, intraocular lenses, high refractive index lenses for spectacles, optical computing, optical storage media, anti-reflection films, conformal coatings, microlens arrays, automotive topcoats, paints, coating agents, hair cosmetics, gradient refractive index optical components and dynamic gradient refractive index components, nanoimprint materials, photocurable plastics, polymerizable compounds for hologram recording, surface coating materials for glass, transparent coating materials for solar cells, plastic lenses, printing plates, semiconductor light-emitting elements (light-emitting diodes, organic light-emitting diodes, laser diodes), light guides (both planar and “fiber” geometric shapes), semiconductor elements, light diffusing members, prism sheets, hard coat materials, optical wiring members, diffraction gratings, sealing materials for LEDs and the like, pressure-sensitive adhesives, protective films used on the surfaces of glass, films or sheets used in sensor elements such as CCD/CMOS and display elements such as displays, photocurable resins (OCR) used to bond image display members such as liquid crystal and plastic cover panels, reflective protective films used in transparent electrodes and the like, index matching to prevent skeletal exposure of ITO electrodes of touch panels, anti-blocking layers, anti-reflection films for displays, and interlayer insulating films for semiconductors. In particular, the alkali-soluble resin and alkali-soluble resin composition of the present invention are suitable for use in microlens arrays and nanoimprint materials because the resin has flexibility.

Furthermore, the alkali-soluble resin and alkali-soluble resin composition of the present invention are particularly suitable as a curable resin or resin composition for optical materials, and can provide a cured film having excellent transparency, excellent substrate adhesion, and excellent electrical properties, for example.

In the present invention, the term “optical materials” refers to materials used for components of devices in the optical field or the electrical and electronic field, and refers to materials used for components such as color filters, light extraction layers, black matrices, photospacers, black column spacers, photoresists, overcoats, planarizing layers for TFTs, insulating films for TFTs, and surface coatings for optical lenses, used in devices such as liquid crystal, organic EL, quantum dot, mini/micro LED display devices, solid-state imaging devices, and touch panel display devices. The resin of the present invention having alkali solubility can be suitably used in applications where photolithography is applied, and can form a cured film having a high refractive index, high hardness, high transparency, and high dielectric constant. Thus, the resin composition of the present invention is most preferably a curable resin composition for use in color filters, light extraction layers, or color conversion layers for organic EL display devices. Examples of light sources for the light extraction layers include various options such as LED, mini/micro LED, and quantum dots. Organic EL is preferably used because it can achieve flexibility. Specific examples of the light extraction layers for organic EL include the configuration described in JP 2021-34545 A. The alkali-soluble resin and alkali-soluble resin composition of the present invention are suitably usable as a highly transparent and refractive material that is applicable to photolithography.

### EXAMPLES

The present invention is described in more detail below with reference to examples, but is not limited to these examples. It should be noted that the terms “part(s)” and “%” refer to “part(s) by mass” and “% by mass”, respectively, unless otherwise stated.

The following describes the evaluation methods used in the EXAMPLES.

### <Acid Value>

A 0.5-g portion of the resin solution was precisely weighed out and dissolved in a solvent mixture of 90 g of acetone and 10 g of water, and the resulting solution was titrated using a 0.1 N KOH aqueous solution as a titrant. The titration was performed using an automatic titrator (product name: COM-555, available from HIRANUMA Co., Ltd.), and the acid value per gram of solids (mg KOH/g) was calculated from the acid value of the resin solution and the amount of solids in the resin solution.

The amount of solids in the resin solution was determined by the following method. Specifically, about 1 g of the resin solution was weighed out in an aluminum cup, about 1 g of acetone was added thereto to dissolve, and the solution was then naturally dried at room temperature. Then, the resulting sample was dried at 160° C. for 1.5 hours using a hot air dryer (product name: PHH-101, available from Espec Corporation), and then cooled in a desiccator. The mass of the resulting sample was measured. The amount of mass loss was determined and the amount of solids (% by mass) in the resin solution was calculated therefrom.

<Double Bond Equivalent (g/Eq)>

The double bond equivalent was determined by dividing the mass of the solids (g) in the resin solution by the amount of double bonds (mol) of the resin. The amount of double bonds was determined by dividing the mass of the compound having polymerizable double bonds used for introducing polymerizable double bonds by the molecular weight.

### <Heat Discoloration Resistance>

The obtained resin solution was uniformly applied to a 5 cm square glass substrate (soda-lime glass AS-2K, available from Toshin Riko Co., Ltd.) using a spin coater (1H-D7, available from Mikasa Co., Ltd.). The coated plate was dried at 90° C. for three minutes to obtain a laminate in which a coating film was formed on the glass substrate. The resin adhering to the edge portion of the glass substrate was removed, and the obtained laminate was subjected to a heat treatment at 230° C. for 30 minutes using a perfect oven temperature chamber (Espec Corporation) and then cooled to room temperature to obtain a laminate having a film thickness of 15 μm. The coating surface of the obtained laminate was subjected to measurement using a color difference meter ZE6000 (Nippon Denshoku Industries Co., Ltd.) to obtain the b* value after the heating test.

### <Refractive Index>

The obtained resin solution was uniformly applied to a glass substrate (Matsunami slide glass S9111, available from Matsunami Glass Ind., Ltd.) using a spin coater (1H-D7, available from Mikasa Co., Ltd.). The coated plate was dried at 90° C. for three minutes to obtain a laminate in which a coating film was formed on the glass substrate. The resin adhering to the edge portion of the glass substrate was removed, and the obtained laminate was subjected to a heat treatment at 230° C. for 30 minutes using a perfect oven temperature chamber (Espec Corporation) and then cooled to room temperature to obtain a laminate having a film thickness of 0.5 μm. The refractive index of the resulting laminate was determined by measuring the reflection spectrum. Specifically, the reflectance was measured by the method in which a film formed on a substrate (e.g., a slide glass) as a coating was used as a measurement target sample, the reflectance due to thin film interference was measured, a thin film reflectance simulation was performed using the reflectance based on the Fresnel equation using the device described below, and whereby the refractive index value at 589 nm was calculated.

Device: Film thickness measurement system F-20 available from Filmetrics

Standard fiber stage SS-1 (spot size: 1.5 mm)

### <Quantification of Epoxy Group>

The measurement was performed according to a method in accordance with JIS K 7236:2001. Specifically, 0.5 g of the resin solution was precisely weighed into a beaker, 25 ml of chloroform, 75 ml of acetic acid, and 2 g of tetraethylammonium bromide were added thereto, and the contents were stirred to dissolve. The solution was then titrated with a 0.1 N perchloric acid-acetic acid standard solution using an automatic titrator (product name: COM-555, available from Hiranuma Sangyo Co., Ltd.), and the mass of the resin solution containing 1 equivalent of epoxy groups was calculated.

### <Developability Test>

The resin solution was applied to a 10 cm square glass substrate by spin coating, and then heat-treated (90° C., three minutes). Thereafter, a photomask having openings with a 30 μm line-and-space pattern was placed 50 μm away from the coating film. Through the photomask, the substrate was exposed to light at an exposure dose of 60 mJ/cm² (converted to 365 nm illuminance) using a UV aligner (Japan Science Engineering Co., Ltd., product name “MA-1100”) equipped with a 2.0 kW ultra-high pressure mercury lamp. A 0.05% aqueous potassium hydroxide solution was sprayed using a spin developer to dissolve and remove the unexposed areas, and the remaining exposed areas were developed by rinsing with pure water for 10 seconds, thereby evaluating developability.

Specifically, the coating film developed through the photomask as described above was observed with a surface roughness meter (Ryoka System Inc., product name “VertScan 2.0”), and the time of spraying the 0.05% aqueous potassium hydroxide solution taken to rinse the unexposed areas was defined as the development time. The presence or absence of residues at the development time was also observed.

### <Evaluation of Bending Resistance>

The resin solution was applied to a thickness of 20 to 30 μm on a copper plate having a thickness of 0.5 mm, dried at 80° C. for 30 minutes in a hot air circulation drying oven, and then cooled to room temperature to obtain a coating film. Next, light irradiation at 2 J/cm² was performed using an ultraviolet exposure device to obtain a cured product. This was heated at 150° C. for one hour to prepare a test substrate. Using the test substrate, the bending resistance of the cured coating film was evaluated by a cylindrical mandrel method with a mandrel size of 010 mm.

### <Measurement of Mass Loss>

Using a thermogravimetry-differential thermal analysis (TG-DTA) device, the coated zirconium oxide particles were heated from room temperature to 800° C. at a rate of 10° C./min in an air atmosphere, and the mass loss of the particles was measured. From the mass loss, the proportion of the carboxylate compound coating the metal oxide particles and the proportion of the metal oxide can be determined.

### (Synthesis Example 1) Synthesis of Resin Solution (A-1)

A vessel equipped with a stirrer, a thermometer, a reflux condenser, and a gas inlet tube was charged with 188 parts of 3,3′,5,5′-tetramethyl-4,4′-bis(glycidyloxy)-1,1′-biphenyl (cas. 85954-11-6, epoxy equivalent: 188 g/eq, Gardner color scale: 6), 62.6 parts of bisphenol S, 244.3 parts of propylene glycol monomethyl ether acetate, and 0.3 parts of triphenylphosphine as a reaction catalyst. The contents were reacted at 140° C. for six hours. Quantification of epoxy groups was performed to confirm the completion of the reaction between the phenolic hydroxy groups and the epoxy groups. Subsequently, 43.5 parts of methacrylic acid, 0.9 parts of triphenylphosphine as an esterification catalyst, and 0.4 parts of hydroquinone as a polymerization inhibitor were added thereto. The contents were reacted at 120° C. for 20 hours. The reaction product was measured for an acid value, which was 1.9 mgKOH/g. Subsequently, 88.1 parts of tetrahydrophthalic anhydride was added thereto, and the contents were reacted at 110° C. for five hours with stirring. As a result, a resin solution (A-1) containing 61% of an alkali-soluble resin in a propylene glycol monomethyl ether acetate solution was obtained. Table 1 shows the acid value in terms of solids and double bond equivalent of the resulting resin solution (A-1).

### (Synthesis Example 2) Synthesis of Resin Solution (A-2)

A vessel equipped with a stirrer, a thermometer, a reflux condenser, and a gas inlet tube was charged with 187 parts of 3,3′,5,5′-tetramethyl-4,4′-bis(glycidyloxy)-1,1′-biphenyl (cas. 85954-11-6, epoxy equivalent: 187 g/eq, Gardner color scale: 10), 62.6 parts of bisphenol S, 243.5 parts of propylene glycol monomethyl ether acetate, and 0.3 parts of triphenylphosphine as a reaction catalyst. The contents were reacted at 140° C. for six hours. Quantification of epoxy groups was performed to confirm the completion of the reaction between the phenolic hydroxy groups and the epoxy groups. Subsequently, 43.5 parts of methacrylic acid, 0.9 parts of triphenylphosphine as an esterification catalyst, and 0.4 parts of hydroquinone as a polymerization inhibitor were added thereto. The contents were reacted at 120° C. for 20 hours. The reaction product was measured for an acid value, which was 1.8 mgKOH/g. Subsequently, 87.8 parts of tetrahydrophthalic anhydride was added thereto, and the contents were reacted at 110° C. for five hours with stirring. As a result, a resin solution (A-2) containing 61% of an alkali-soluble resin in a propylene glycol monomethyl ether acetate solution was obtained. Table 1 shows the acid value in terms of solids and double bond equivalent of the resulting resin solution (A-2).

### (Synthesis Example 3) Synthesis of Resin Solution (A-3)

A vessel equipped with a stirrer, a thermometer, a reflux condenser, and a gas inlet tube was charged with 94 parts of 3,3′,5,5′-tetramethyl-4,4′-bis(glycidyloxy)-1,1′-biphenyl (cas. 85954-11-6), which was the same as that used in Synthesis Example 1, 31.3 parts of bisphenol S, 202.3 parts of propylene glycol monomethyl ether acetate, and 0.5 parts of triphenylphosphine as a reaction catalyst. The contents were reacted at 140° C. for six hours. Quantification of epoxy groups was performed to confirm the completion of the reaction between the phenolic hydroxy groups and the epoxy groups. Thereafter, 251.8 parts of bisphenol A epoxy resin (trade name “jER834”, available from Mitsubishi Chemical Corporation, epoxy equivalent: 248 g/eq) and 202.3 parts of propylene glycol monomethyl ether acetate were added and dissolved thereto to obtain a homogeneous solution. Subsequently, the internal temperature was maintained at 110° C., 0.75 parts of triphenylphosphine as an esterification catalyst and 0.6 parts of methylhydroquinone as a polymerization inhibitor were added thereto, and 110 parts of methacrylic acid was continuously added dropwise for two hours using a dropping pump. After the dropwise addition, 0.75 parts of triphenylphosphine was added as an additional catalyst, the temperature was raised to 120° C., and the reaction was performed for 15 hours. The reaction product was measured for an acid value, which was 2.1 mgKOH/g. Subsequently, 145.9 parts of tetrahydrophthalic anhydride was added thereto. The contents were reacted at 110° C. for five hours to obtain a resin solution (A-3) containing 61% of a mixture of an alkali-soluble resin and carboxy group-containing bisphenol A epoxy acrylate in a propylene glycol monomethyl ether acetate solution. Table 1 shows the acid value in terms of solids and double bond equivalent of the resulting resin solution (A-3).

### (Synthesis Example 4) Synthesis of Resin Solution (A-4)

A vessel equipped with a stirrer, a thermometer, a reflux condenser, and a gas inlet tube was charged with 93 parts of 3,3′,5,5′-tetramethyl-4,4′-bis(glycidyloxy)-1,1′-biphenyl (cas. 85954-11-6, epoxy equivalent: 186 g/eq, Gardner color scale: 7), 31.3 parts of bisphenol S, 174.3 parts of propylene glycol monomethyl ether acetate, and 0.5 parts of triphenylphosphine as a reaction catalyst. The contents were reacted at 140° C. for six hours. Quantification of epoxy groups was performed to confirm the completion of the reaction between the phenolic hydroxy groups and the epoxy groups. Thereafter, 251.8 parts of bisphenol A epoxy resin “jER834”, which was the same as that used in Synthesis Example 3, and 174.3 parts of propylene glycol monomethyl ether acetate were added and dissolved thereto to obtain a homogeneous solution. Subsequently, 110 parts of methacrylic acid, 1.5 parts of triphenylphosphine as an esterification catalyst, and 0.5 parts of hydroquinone as a polymerization inhibitor were added thereto. The contents were reacted at 120° C. for 20 hours. The reaction product was measured for an acid value, which was 2.2 mgKOH/g. Subsequently, 59.1 parts of tetrahydrophthalic anhydride was added thereto. The contents were reacted at 110° C. for five hours to obtain a resin solution (A-4) containing 61% of a mixture of an alkali-soluble resin and carboxy group-containing bisphenol A epoxy acrylate in a propylene glycol monomethyl ether acetate solution. Table 1 shows the acid value in terms of solids and double bond equivalent of the resulting resin solution (A-4).

### (Synthesis Example 5) Synthesis of Resin Solution (A-5)

A vessel equipped with a stirrer, a thermometer, a reflux condenser, and a gas inlet tube was charged with 75.2 parts of 3,3′,5,5′-tetramethyl-4,4′-bis(glycidyloxy)-1,1′-biphenyl (cas. 85954-11-6), which was the same as that used in Synthesis Example 1, 25 parts of bisphenol S, 135.5 parts of propylene glycol monomethyl ether acetate, and 0.3 parts of triphenylphosphine as a reaction catalyst. The contents were reacted at 140° C. for six hours. Quantification of epoxy groups was performed to confirm the completion of the reaction between the phenolic hydroxy groups and the epoxy groups. Thereafter, 131.4 parts of cresol novolac epoxy resin (trade name “EOCN-104S”, Nippon Kayaku Co., Ltd., epoxy equivalent: 219 g/eq) and 135.5 parts of propylene glycol monomethyl ether acetate were added and dissolved thereto to obtain a homogeneous solution. Subsequently, 69.6 parts of methacrylic acid, 0.9 parts of triphenylphosphine as an esterification catalyst, and 0.4 parts of methylhydroquinone as a polymerization inhibitor were added thereto. The contents were reacted at 120° C. for 20 hours. The reaction product was measured for an acid value, which was 1.9 mgKOH/g. Subsequently, 122.7 parts of tetrahydrophthalic anhydride was added thereto. The contents were reacted at 110° C. for five hours to obtain a resin solution (A-5) containing 61% of a mixture of an alkali-soluble resin and carboxy group-containing novolac epoxy acrylate in a propylene glycol monomethyl ether acetate solution. Table 1 shows the acid value in terms of solids and double bond equivalent of the resulting resin solution (A-5).

### (Synthesis Example 6) Synthesis of Resin Solution (A-6)

A vessel equipped with a stirrer, a thermometer, a reflux condenser, and a gas inlet tube was charged with 94 parts of 3,3′,5,5′-tetramethyl-4,4′-bis(glycidyloxy)-1,1′-biphenyl (cas. 85954-11-6), which was the same as that used in Synthesis Example 1, 31.3 parts of bisphenol S, 202.3 parts of propylene glycol monomethyl ether acetate, and 0.5 parts of triphenylphosphine as a reaction catalyst. The contents were reacted at 140° C. for six hours. Quantification of epoxy groups was performed to confirm the completion of the reaction between the phenolic hydroxy groups and the epoxy groups. Thereafter, 251.8 parts of bisphenol A epoxy resin (trade name “jER834”, available from Mitsubishi Chemical Corporation, epoxy equivalent: 248 g/eq) and 202.3 parts of propylene glycol monomethyl ether acetate were added and dissolved thereto to obtain a homogeneous solution. Subsequently, the internal temperature was maintained at 110° C., 0.75 parts of triphenylphosphine as an esterification catalyst and 0.6 parts of hydroquinone as a polymerization inhibitor were added thereto, and 110 parts of methacrylic acid was continuously added dropwise for two hours using a dropping pump. After the dropwise addition, 0.75 parts of triphenylphosphine was added as an additional catalyst, the temperature was raised to 120° C., and the reaction was performed for 15 hours. The reaction product was measured for an acid value, which was 2.1 mgKOH/g. Subsequently, 145.9 parts of tetrahydrophthalic anhydride was added thereto. The contents were reacted at 110° C. for five hours to obtain a resin solution (A-6) containing 61% of a mixture of an alkali-soluble resin and carboxy group-containing bisphenol A epoxy acrylate in a propylene glycol monomethyl ether acetate solution. Table 1 shows the acid value in terms of solids and double bond equivalent of the resulting resin solution (A-6).

### (Synthesis Example 7) Synthesis of Resin Solution (A-7)

A vessel equipped with a stirrer, a thermometer, a reflux condenser, and a gas inlet tube was charged with 248 parts of bisphenol A epoxy resin “jER834”, which was the same as that used in Synthesis Example 3, 87 parts of methacrylic acid, 278.3 parts of propylene glycol monomethyl ether acetate, 1 part of triphenylphosphine as an esterification catalyst, and 0.4 parts of hydroquinone as a polymerization inhibitor. The contents were reacted at 120° C. for 20 hours. The reaction product was measured for an acid value, which was 1.8 mgKOH/g. Subsequently, 100.3 parts of tetrahydrophthalic anhydride was added thereto. The contents were reacted at 110° C. for five hours to obtain a resin solution (A-7) containing 61% of carboxy group-containing bisphenol A epoxy acrylate in a propylene glycol monomethyl ether acetate solution. Table 1 shows the acid value in terms of solids and double bond equivalent of the resulting resin solution (A-7).

### (Synthesis Example 8) Synthesis of Resin Solution (B-1)

A vessel equipped with a stirrer, a thermometer, a reflux condenser, and a gas inlet tube was charged with 94 parts of 3,3′,5,5′-tetramethyl-4,4′-bis(glycidyloxy)-1,1′-biphenyl (cas. 85954-11-6), which was the same as that used in Synthesis Example 1, 31.3 parts of bisphenol S, 202.3 parts of propylene glycol monomethyl ether acetate, and 0.5 parts of benzyltriethylammonium chloride as a reaction catalyst. The contents were reacted at 140° C. for six hours. Quantification of epoxy groups was performed to confirm the completion of the reaction between the phenolic hydroxy groups and the epoxy groups. Thereafter, 251.8 parts of bisphenol A epoxy resin “jER834”, which was the same as that used in Synthesis Example 3, and 202.3 parts of propylene glycol monomethyl ether acetate were added and dissolved thereto to obtain a homogeneous solution. Subsequently, 110 parts of methacrylic acid, 1.5 parts of triphenylphosphine as an esterification catalyst, and 0.6 parts of methylhydroquinone as a polymerization inhibitor were added thereto. The contents were reacted at 120° C. for 20 hours. The reaction product was measured for an acid value, which was 2.5 mgKOH/g. Subsequently, 145.9 parts of tetrahydrophthalic anhydride was added thereto. The contents were reacted at 110° C. for five hours to obtain a resin solution (B-1) containing 61% of a mixture of a comparative alkali-soluble resin and carboxy group-containing bisphenol A epoxy acrylate in a propylene glycol monomethyl ether acetate solution. Table 1 shows the acid value in terms of solids and double bond equivalent of the resulting resin solution (B-1).

### (Synthesis Example 9) Synthesis of Resin Solution (B-2)

A vessel equipped with a stirrer, a thermometer, a reflux condenser, and a gas inlet tube was charged with 113 parts of bisphenol A epoxy resin “jER834”, which was the same as that used in Synthesis Example 3, 63.2 parts of another bisphenol A epoxy resin (product name “YD-901”, available from NIPPON STEEL Chemical & Material Co., Ltd., epoxy equivalent: 464 g/eq), 51.5 parts of methacrylic acid, 189.1 parts of propylene glycol monomethyl ether acetate, 0.7 parts of triphenylphosphine as an esterification catalyst, and 0.3 parts of hydroquinone as a polymerization inhibitor. The contents were reacted at 120° C. for 20 hours. The reaction product was measured for an acid value, which was 2.0 mgKOH/g. Subsequently, 68.2 parts of tetrahydrophthalic anhydride was added thereto. The contents were reacted at 110° C. for five hours to obtain a resin solution (B-2) containing 61% of carboxy group-containing bisphenol A epoxy acrylate in a propylene glycol monomethyl ether acetate solution. Table 1 shows the acid value in terms of solids and double bond equivalent of the resulting resin solution (B-2).

### (Synthesis Example 10) Synthesis of Resin Solution (B-3)

A vessel equipped with a stirrer, a thermometer, a reflux condenser, and a gas inlet tube was charged with 94 parts of 3,3′,5,5′-tetramethyl-4,4′-bis(glycidyloxy)-1,1′-biphenyl (cas. 85954-11-6, epoxy equivalent: 188 g/eq, Gardner color scale: 13), 31.3 parts of bisphenol S, 202.3 parts of propylene glycol monomethyl ether acetate, and 0.5 parts of triphenylphosphine as a reaction catalyst. The contents were reacted at 140° C. for six hours. Quantification of epoxy groups was performed to confirm the completion of the reaction between the phenolic hydroxy groups and the epoxy groups. Thereafter, 251.8 parts of bisphenol A epoxy resin (trade name “jER834”, available from Mitsubishi Chemical Corporation, epoxy equivalent: 248 g/eq) and 202.3 parts of propylene glycol monomethyl ether acetate were added and dissolved thereto to obtain a homogeneous solution. Subsequently, 110 parts of methacrylic acid, 1.5 parts of triphenylphosphine as an esterification catalyst, and 0.6 parts of methylhydroquinone as a polymerization inhibitor were added thereto. The contents were reacted at 120° C. for 20 hours. The reaction product was measured for an acid value, which was 2.1 mgKOH/g. Subsequently, 145.9 parts of tetrahydrophthalic anhydride was added thereto. The contents were reacted at 110° C. for five hours to obtain a resin solution (B-3) containing 61% of a mixture of an alkali-soluble resin and carboxy group-containing bisphenol A epoxy acrylate in a propylene glycol monomethyl ether acetate solution. Table 1 shows the acid value in terms of solids and double bond equivalent of the resulting resin solution (B-3). The resin solution (B-3) was brownish in color compared to the resin solution (A-3).

### (Synthesis Example 11) Synthesis of Resin Solution (B-4)

A reaction tank equipped with a thermometer, a stirrer, a gas inlet tube, a cooling tube, and inlets for dropping vessels was charged with 119.2 parts of propylene glycol monomethyl ether acetate and 50.7 parts of propylene glycol monomethyl ether, purged with nitrogen, and heated to 90° C.

Separately, a dropping tank (A) was charged with 55.0 parts of benzyl methacrylate, 45.0 parts of methacrylic acid, and 1.0 parts of t-butylperoxy-2-ethylhexanoate, which were mixed by stirring, and a dropping tank (B) was charged with 2.8 parts of n-dodecyl mercaptan and 15.9 parts of propylene glycol monomethyl ether acetate, which were mixed by stirring.

After the temperature of the reaction tank reached 90° C., dropwise addition from the dropping tanks was started and performed over three hours to carry out polymerization, while the temperature was maintained. After the dropwise addition, the temperature was kept at 90° C. for 30 minutes, and then raised to 115° C., followed by aging for 90 minutes. To the obtained base polymer solution were added 41.3 parts of glycidyl methacrylate, 0.4 parts of triethylamine, and 0.2 parts of ANTAGE W-400. The temperature was raised to 115° C. while bubbling a gas mixture of oxygen and nitrogen having an oxygen concentration adjusted to 7% at 20 ml/min, followed by an eight-hour reaction. Thereafter, the reaction product was cooled to room temperature to obtain a resin solution (B-4) containing an alkali-soluble resin. Table 2 shows the acid value in terms of solids and double bond equivalent of the resulting resin solution (B-4).

### <Preparation of Inorganic Fine Particle>

### Production Example 1

(Production of Zirconium Oxide Nanoparticle (Coated ZrO₂ Particle 1) Coated with 2-Ethylhexanoic Acid and/or Carboxylate Derived from 2-Ethylhexanoic Acid)

A solution of zirconium 2-ethylhexanoate in a mineral spirit (782 g, zirconium 2-ethylhexanoate content: 44% by mass, available from Daiichi Kigenso Kagaku Kogyo Co., Ltd.) was mixed with pure water (268 g). The resulting solution mixture was placed in an autoclave equipped with a stirrer, and the atmosphere inside the autoclave was replaced by nitrogen gas. Thereafter, the solution mixture was heated to 180° C. and kept at that temperature for 16 hours (the pressure inside the autoclave was 0.94 MPa) for reaction, thereby producing zirconium oxide particles. Subsequently, the reacted solution mixture was taken out, and the precipitate that had accumulated at the bottom was collected by filtration, washed with acetone, and then dried. The dried precipitate (100 g) was dispersed in toluene (800 mL) to obtain a turbid solution. Next, as a purification step, the solution was filtered again through quantitative filter paper (Advantec Toyo Kaisha, Ltd., No. 5C) to remove coarse particles and the like in the precipitate. Furthermore, the filtrate was concentrated under reduced pressure to remove the toluene, and white zirconium oxide nanoparticles 1 (coated ZrO₂ particles 1) were collected.

The crystal structure of the obtained coated ZrO₂ particles 1 was examined by the XRD diffraction pattern. As a result, diffraction lines assigned to tetragonal crystals and monoclinic crystals were detected, the ratio of tetragonal crystals to monoclinic crystals was found to be 54/46 from the intensity of the diffraction lines, and the particle size (crystallite size) was found to be 5 nm.

The coated ZrO₂ particles 1 had an average particle size (number average primary particle size) of 12 nm, which was measured with an electron microscope (FE-TEM JEM-2100F, available from JEOL Ltd., 600000 magnification). Also, analysis of the obtained coated ZrO₂ particles 1 by infrared absorption spectroscopy revealed an absorption due to C—H and an absorption due to COOH. These absorptions are believed to be due to 2-ethylhexanoic acid and/or a carboxylate derived from 2-ethylhexanoic acid coating the surfaces of the coated ZrO₂ particles 1.

Furthermore, the mass loss of the coated ZrO₂ particles 1 measured according to the above <Measurement of mass loss> was 12% by mass. This revealed that the amount of 2-ethylhexanoic acid and/or a carboxylate derived from 2-ethylhexanoic acid coating the surfaces of the coated ZrO₂ particles 1 was 12% by mass of the entire coated ZrO₂ particles 1.

### Production Example 2

(Production of Zirconium Oxide Nanoparticle (Coated ZrO₂ Particle 2) Coated with 2-Acryloyloxyethyl Succinate and 2-Ethylhexanoic Acid and/or Carboxylate Derived from 2-Ethylhexanoic Acid)

The coated ZrO₂ particles 1 (10 g) obtained in Production Example 1 and 2-acryloyloxyethyl succinate (1.5 g) were mixed by stirring in propylene glycol monomethyl ether acetate (12 g, hereinafter referred to as “PGMEA”) until uniformly dispersed. Subsequently, n-hexane (36 g) was added thereto to aggregate the dispersed particles, making the solution turbid, and the aggregated particles were separated from the turbid solution using filter paper. Thereafter, the separated aggregated particles were added to n-hexane (36 g), followed by stirring for 10 minutes, and separated using filter paper. The resulting particles were dried in vacuum at room temperature to prepare zirconium oxide nanoparticles (coated ZrO₂ particles 2) surface-treated with 2-acryloyloxyethyl succinate and 2-ethylhexanoic acid and/or a carboxylate derived from 2-ethylhexanoic acid.

The coated ZrO₂ particles 2 were dispersed in deuterated chloroform to prepare a measurement sample, which was then analyzed by 1H-NMR. As a result, it was found that the molar ratio of 2-ethylhexanoic acid and/or a carboxylate derived from 2-ethylhexanoic acid to 2-acryloyloxyethyl succinate was 24:76.

The mass loss of the coated ZrO₂ particles 2 measured according to the above <Measurement of mass loss> was 18% by mass. This revealed that the amount of 2-acryloyloxyethyl succinate and 2-ethylhexanoic acid and/or a carboxylate derived from 2-ethylhexanoic acid coating the coated zirconium oxide particles was 18% by mass of the entire coated zirconium oxide particles.

The coated ZrO₂ particles 2 (7 g) obtained above, methyl ethyl ketone (3 g), and DISPER BYK-111 (BYK JAPAN KK, 0.14 g) were mixed and stirred uniformly to obtain a zirconia particle dispersion. The coated ZrO₂ particles 2 had a number average primary particle size of 12 nm, which was measured by an electron microscope.

### Examples 1 to 8 and Comparative Examples 1 to 4

The resin solutions obtained in Synthesis Examples 1 to 11 according to the formulations shown in Table 3 and alkali-soluble resin compositions containing any of these solutions were evaluated for heat discoloration resistance and refractive index by the above-described methods. Table 3 shows the results. The values shown in Table 3 are the amounts of solids of the resins.

### Examples 9 and 10 and Comparative Example 5

An alkali-soluble resin composition was prepared by mixing propylene glycol monomethyl ether acetate (PGMEA) with any of the resin solutions having the formulations (amounts of solids) shown in Table 4, a mill base (MB), dipentaerythritol hexaacrylate (DPHA), and a photopolymerization initiator (Irgacure 907, available from BASF) so that the amount of solids in the composition was 20%. The developability of the resulting alkali-soluble resin compositions was evaluated by the above-described method. Table 4 shows the results.

The mill base (MB) used was prepared by the following method.

### (Preparation of Mill Base)

The mill base (MB) was obtained by mixing 12.9 parts of propylene glycol monomethyl ether acetate, 0.4 parts of Disparlon DA-7301 as a dispersant, and 2.25 parts of C.I. Pigment Green 58 and 1.5 parts of C.I. Pigment Yellow 138 as coloring materials, followed by dispersing with a paint shaker for three hours.

### Examples 11 to 13 and Comparative Example 6

A resin composition was prepared by mixing propylene glycol monomethyl ether acetate (PGMEA) with any of the resin solutions having the formulations (amounts of solids) shown in Table 5, dipentaerythritol hexaacrylate (DPHA), and a photopolymerization initiator (Irgacure 907, available from BASF) so that the amount of solids in the composition was 30%. The bending resistance of the resulting resin compositions was evaluated by the above-described method. Table 5 shows the results.

TABLE 1

| | | | Synthe- | Synthe- | Synthe- | Synthe- | Synthe- | Synthe- | Synthe- | Synthe- | Synthe- | Synthe- |
|---|---|---|---|---|---|---|---|---|---|---|---|---|
| | | | sis | sis | sis | sis | sis | sis | sis | sis | sis | sis |
| | | | Exam- | Exam- | Exam- | Exam- | Exam- | Exam- | Exam- | Exam- | Exam- | Exam- |
| | | | ple 1 | ple 2 | ple 3 | ple 4 | ple 5 | ple 6 | ple 7 | ple 8 | ple 9 | ple 10 |
| | Resin solution | | A-1 | A-2 | A-3 | A-4 | A-5 | A-6 | A-7 | B-1 | B-2 | B-3 |
| Step 1 | Bifunctional | 3,3′,5,5′- | 188 | 187 | 94 | 93 | 75.2 | 94 | — | 94 | — | 94 |
| | epoxy | Tetramethyl-4,4′- | (188) | (187) | (188) | (186) | (188) | (188) | | (188) | | (188) |
| | compound | bis(glycidyloxy)- | | | | | | | | | | |
| | | 1,1′-biphenyl | | | | | | | | | | |
| | | (epoxy | | | | | | | | | | |
| | | equivalent (g/eq)) | | | | | | | | | | |
| | | Gardner color scale | 6 | 10 | 6 | 7 | 6 | 6 | — | 6 | — | 13 |
| | | of the raw material | | | | | | | | | | |
| | Bisphenol | Bisphenol S | 62.6 | 62.6 | 31.3 | 31.3 | 25 | 31.3 | — | 31.3 | — | 31.3 |
| | compound | | | | | | | | | | | |
| Step 2 | Epoxy resin | jER834 (epoxy | — | — | 251.8 | 251.8 | — | 251.8 | 248 | 251.8 | 113 | 251.8 |
| | | equivalent (g/eq)) | | | (248) | (248) | | (248) | (248) | (248) | (248) | (248) |
| | | EOCN-104S (epoxy | — | — | — | — | 131.4 | — | — | — | — | — |
| | | equivalent (g/eq)) | | | | | (219) | | | | | |
| | | YD-901 (epoxy | — | — | — | — | — | — | — | — | 63.2 | — |
| | | equivalent (g/eq)) | | | | | | | | | (464) | |
| Step 3 | Unsaturated | Methacrylic acid | 43.5 | 43.5 | 110 | 110 | 69.6 | 110 | 87 | 110 | 51.5 | 110 |
| | monobasic | | | | | | | | | | | |
| | acid | | | | | | | | | | | |
| Step 4 | Polybasic | Tetrahydrophthalic | 88.1 | 87.8 | 145.9 | 59.1 | 122.7 | 145.9 | 100.3 | 145.9 | 68.2 | 145.9 |
| | acid | anhydride | | | | | | | | | | |
| | anhydride | | | | | | | | | | | |

| Catalyst | Triphenylphosphine | 0.3 + | 0.3 + | 0.5 + | 0.5 + | 0.3 + | 0.5 + | 1 | 1.5 | 0.7 | 0.5 + |
|---|---|---|---|---|---|---|---|---|---|---|---|
| | | 0.9 | 0.9 | 1.5 | 1.5 | 0.9 | 1.5 | | | | 1.5 |
| | Benzyltriethyl- | — | — | — | — | — | — | — | — | — | — |
| | ammonium chloride | | | | | | | | | | |
| | <Ammonium salt | 0 | 0 | 0 | 0 | 0 | 0 | 0 | 0.079 | 0 | 0 |
| | content (wt %/ | | | | | | | | | | |
| | resin solids)> | | | | | | | | | | |
| Polymerization | Hydroquinone | 0.4 | 0.4 | — | 0.5 | — | 0.6 | 0.4 | — | 0.3 | — |
| inhibitor | Methylhydroquinone | — | — | 0.6 | — | 0.4 | — | — | 0.6 | — | 0.6 |

| | | | | | | | | | | |
|---|---|---|---|---|---|---|---|---|---|---|
| Acid value (mgKOH/g) | 89 | 89 | 89 | 44 | 110 | 89 | 88 | 90 | 89 | 89 |
| Double bond equivalent (g/eq) | 760 | 760 | 500 | 430 | 530 | 500 | 440 | 500 | 500 | 500 |

TABLE 2

| | | Synthesis |
|---|---|---|
| | | Example 11 |
| Resin solution | | B-4 |
| Polymerization | Benzyl methacrylate | 55.0 |
| step | Methacrylic acid | 45.0 |
| Addition step | Glycidyl methacrylate | 41.3 |

| | |
|---|---|
| Acid value (mgKOH/g) | 90 |
| Double bond equivalent (g/eq) | 500 |

TABLE 3

| | | | | | | | | | | Compar- | Compar- | Compar- | Compar- |
|---|---|---|---|---|---|---|---|---|---|---|---|---|---|
| | | Exam- | Exam- | Exam- | Exam- | Exam- | Exam- | Exam- | Exam- | ative | ative | ative | ative |
| (Parts) | | ple 1 | ple 2 | ple 3 | ple 4 | ple 5 | ple 6 | ple 7 | ple 8 | Example 1 | Example 2 | Example 3 | Example 4 |
| Resin | A-1 | 100 | 30 | — | — | — | — | — | — | — | — | — | — |
| solution | A-2 | — | — | 30 | — | — | — | — | — | — | — | — | — |
| | A-3 | — | — | — | 100 | — | — | 50 | — | — | — | — | — |
| | A-4 | — | — | — | — | 100 | — | — | — | — | — | — | — |
| | A-5 | — | — | — | — | — | 100 | — | — | — | — | — | — |
| | A-6 | — | — | — | — | — | — | — | 50 | — | — | — | — |
| | A-7 | — | 70 | 70 | — | — | — | — | — | — | — | — | — |
| | B-1 | — | — | — | — | — | — | — | — | 100 | — | — | — |
| | B-2 | — | — | — | — | — | — | — | — | — | 100 | — | — |
| | B-3 | — | — | — | — | — | — | — | — | — | — | 100 | — |
| | B-4 | — | — | — | — | — | — | — | — | — | — | — | 100 |
| Inorganic | Particle 2 | — | — | — | — | — | — | 50 | 50 | — | — | — | — |
| particle | | | | | | | | | | | | | |

| | | | | | | | | | | | | |
|---|---|---|---|---|---|---|---|---|---|---|---|---|
| b* | 5.9 | 4.5 | 5.2 | 4.2 | 4.3 | 5.3 | 4.1 | 4.1 | 7.6 | 6.1 | 6.2 | 6.2 |
| Refractive index | 1.61 | 1.58 | 1.59 | 1.60 | 1.59 | 1.57 | 1.71 | 1.72 | 1.56 | 1.54 | 1.55 | 1.52 |

TABLE 4

| | | | Comparative |
|---|---|---|---|
| (Parts) | Example 9 | Example 10 | Example 5 |
| A-3 | 35 | — | — |
| A-4 | — | 35 | — |
| B-4 | — | — | 35 |
| MB | 30 | | |
| DPHA | 30 | | |
| Irg907 | 5 | | |
| PGMEA | Amount to make amount of solids 20% | | |
| Development | 10 | 15 | 30 |
| speed (sec) | | | |
| Residue | Absent | Absent | Present |

TABLE 5

| | | | | Comparative |
|---|---|---|---|---|
| (Parts) | Example 11 | Example 12 | Example 13 | Example 6 |
| A-1 | 30 | — | — | — |
| A-3 | — | 100 | — | — |
| A-6 | — | — | 100 | — |
| A-7 | 70 | — | — | — |
| B-3 | — | — | — | 100 |
| DPHA | 10 | | | |
| Irg907 | 5 | | | |
| PGMEA | Amount to make amount of solids 30% | | | |
| Bending | No cracking | Slight cracking | No cracking | Cracking and |
| resistance | or peeling | and no peeling | or peeling | peeling |

Table 3 demonstrates that the resin solutions of Examples 1 to 8 achieved both excellent heat discoloration resistance and a high refractive index. Also, in Examples 7 and 8 in which inorganic fine particles were added, improved heat discoloration resistance and a higher refractive index were achieved.

As shown in the comparative examples, the resin containing the resin solution (B-1) had extremely poor heat discoloration resistance because it contained an ammonium salt (Comparative Example 1). The resin not containing the skeleton of the formula (1), i.e., the resin solution (B-2), had a low refractive index (Comparative Example 2). A resin prepared from a raw material having a high Gardner color scale, such as the resin solution (B-3), had extremely poor heat discoloration resistance (Comparative Example 3). Also, the resins of the examples achieve a high level of refractive index that could not be achieved with an acrylic resin such as the resin solution (B-4).

Table 4 demonstrates that the resin compositions prepared using the resin solutions of the examples advantageously have a higher development speed and have less residue than the resin composition including acrylic resin.

Table 5 demonstrates that the resin compositions prepared using the resin solutions of the examples had better bending resistance than the resin composition prepared using the resin solution of the comparative example. This is presumably because the resin prepared using a raw material with a high Gardner color scale was susceptible to oxidative deterioration and became brittle.

In addition, the comparison between the examples demonstrates that the resin compositions prepared using the resin solutions A-1 and A-7 prepared with hydroquinone as a polymerization inhibitor had better bending resistance than the resin composition prepared using the resin solution A-3 prepared with methylhydroquinone as a polymerization inhibitor. The hydroquinone present in the resin compositions differs from methylhydroquinone in that the hydroquinone has no substituents other than the phenolic hydroxy groups and is not subject to steric hindrance. Thus, each of these two phenolic hydroxy groups is considered to easily interact with the resin skeleton. Therefore, the hydroquinone is believed to easily act as a buffer between the resin skeletons and is advantageous in improving flexibility.

In addition, although not shown in the tables, display devices including color filters prepared using the resin solutions (A-1) to (A-7) as raw materials had good voltage retention ratios, whereas a display device including a color filter prepared using the resin solution (B-1) had leakage of ionic compounds into the liquid crystal layer and had significantly poor voltage holding ratio.

1. An alkali-soluble resin having a structure represented by the following formula (1),
the alkali-soluble resin comprising an ammonium salt compound in an amount of 0.06% by mass or less relative to 100% by mass of the alkali-soluble resin,
the formula (1) being as follows: 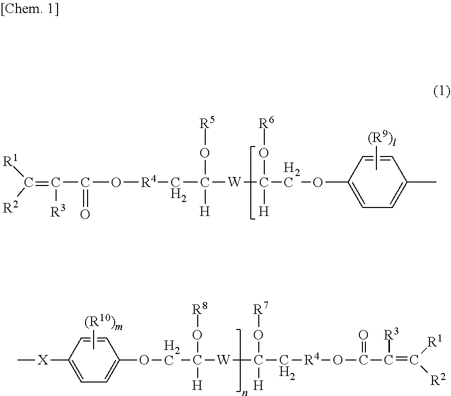
wherein R¹, R², and R³ are the same as or different from each other and each represent a hydrogen atom or a C1-C6 hydrocarbon group; R⁴ represents a direct bond or a divalent organic group; R⁵, R⁶, R⁷, and R⁸ are the same as or different from each other and each represent a hydrogen atom or Y, with at least one of R⁵ to R³ being Y, where Y is a group represented by the following formula (2); R⁹ and R¹⁰ are the same as or different from each other and each represent a substituent; W represents a divalent organic group; X represents a direct bond or a divalent organic group; 1 represents the number of R⁹ and is an integer of 0 to 4; m represents the number of R¹⁰ and is an integer of 0 to 4; when multiple R⁹s are present, they are the same as or different from each other, and when multiple R¹⁰s are present, they are the same as or different from each other; and n is an integer of 1 or more,
the formula (2) being as follows: 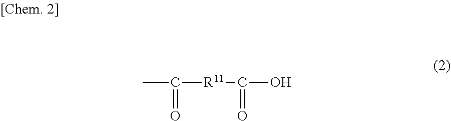
wherein R¹¹ represents a divalent organic group optionally containing a substituent.

2. An alkali-soluble resin composition comprising:
the alkali-soluble resin according to claim 1; and
an acid group-containing epoxy (meth)acrylate.

3. A method for producing an alkali-soluble resin, the method comprising:
a step (a-1) of reacting a bisphenol compound with a bifunctional epoxy compound having a Gardner color scale based on JIS K 0071-2 of less than 12 and a melting point of 90° C. or higher;
a step (a-2) of reacting a reaction product obtained in the step (a-1) with an unsaturated monobasic acid; and
a step (a-3) of reacting a reaction product obtained in the step (a-2) with a polybasic acid anhydride,
wherein the alkali-soluble resin obtained by the production method comprises an ammonium salt compound in an amount of 0.06% by mass or less relative to 100% by mass of the alkali-soluble resin.

4. A method for producing an alkali-soluble resin composition, the method comprising:
a step (b-1) of reacting a bisphenol compound with a bifunctional epoxy compound having a Gardner color scale based on JIS K 0071-2 of less than 12 and a melting point of 90° C. or higher;
a step (b-2) of adding an epoxy resin to a reaction product obtained in the step (b-1);
a step (b-3) of reacting a mixture obtained in the step (b-2) with an unsaturated monobasic acid; and
a step (b-4) of reacting a reaction mixture obtained in the step (b-3) with a polybasic acid anhydride,
wherein the alkali-soluble resin composition obtained by the production method comprises an ammonium salt compound in an amount of 0.06% by mass or less relative to 100% by mass of the alkali-soluble resin.

5. The method for producing an alkali-soluble resin composition according to claim 4,
wherein the epoxy resin is an aromatic epoxy resin.

6. The method for producing an alkali-soluble resin composition according to claim 5,
wherein the aromatic epoxy resin is a bisphenol A epoxy resin.
